(19) United States
(12) Patent Application Publication
(10) Pub. No.: US 2025/0386677 A1
(43) Pub. Date: Dec. 18, 2025

(54) DISPLAY DEVICE, METHOD OF MANUFACTURING THE SAME AND DEPOSITION MASK

(71) Applicant: Samsung Display Co., Ltd., Yongin-si (KR)

(72) Inventors: Sung Hyun PARK, Yongin-si (KR); Joo Hong SEO, Yongin-si (KR); Ho Won JANG, Yongin-si (KR)

(21) Appl. No.: 19/227,217

(22) Filed: Jun. 3, 2025

(30) Foreign Application Priority Data
Jun. 18, 2024 (KR) 10-2024-0078975
Jul. 9, 2024 (KR) 10-2024-0090706

(51) Int. Cl. H10K 59/122; C23C 16/04; H10K 59/12; H10K 59/80; H10K 71/16

(52) U.S. Cl. CPC H10K 59/122; C23C 16/042; H10K 59/1201; H10K 59/80521; H10K 59/80522; H10K 71/166

(57) ABSTRACT

A display device includes: a pixel including one or more subpixels, the sub-pixels each having an emission area to emit light and the pixel having a non-emission area around the emission areas of the sub-pixels, a pixel define layer overlapping the non-emission area, defining trenches in a boundary region between adjacent sub-pixels of the sub-pixels and the trenches penetrating the pixel define layer, an emission structure on portions of the trenches and the pixel define layer, a cathode on the emission structure, and an auxiliary electrode on a portion of the cathode.

### CROSS-REFERENCE TO RELATED APPLICATION

The present application claims priority to and the benefit of Korean Patent Application No. 10-2024-0078975, filed on Jun. 18, 2024, and Application No. 10-2024-0090706, filed on Jul. 9, 2024, in the Korean Intellectual Property Office, the entire disclosure of each of which is incorporated herein by reference.

### BACKGROUND

### 1. Field

Embodiments of the present disclosure relate to a display device, a method of manufacturing the display device, and a deposition mask.

### 2. Description of Related Art

With the development of information technology, the importance of display devices, which are connection mediums between users and information, has increased.

### SUMMARY

Aspects of embodiments of the present disclosure are directed toward a display device with increased cathode connectivity, a method of manufacturing the display device, and a deposition mask.

Additional aspects will be set forth in part in the description which follows and, in part, will be apparent from the description, or may be learned by practice of the presented embodiments of the disclosure.

According to one or more embodiments of the present disclosure, a display device includes: a pixel including one or more sub-pixels, the sub-pixels each having an emission area to emit light and the pixel having a non-emission area around the emission areas of the sub-pixels, a pixel define layer overlapping the non-emission area, and defining trenches in a boundary region between adjacent sub-pixels of the sub-pixels, the trenches penetrating the pixel define layer, an emission structure on portions of the trenches and the pixel define layer, a cathode on the emission structure, and an auxiliary electrode partially on a portion of the cathode.

In one or more embodiments, the auxiliary electrode may be on the portion of the cathode overlapping the boundary region.

In one or more embodiments, the cathode may overlap non-boundary regions adjacent to the boundary region, and the auxiliary electrode may not overlap the non-boundary regions.

In one or more embodiments, the auxiliary electrode may include a conductive material.

In one or more embodiments, the auxiliary electrode may include indium zinc oxide, aluminum, or silver.

In one or more embodiments, the display device may further include an encapsulation layer covering the cathode and the auxiliary electrode.

In one or more embodiments of the present disclosure, the emission structure may include: a first emission part including a first hole transport portion, a first emission layer, and a first electron transport portion, a second emission part including a second hole transport portion, a second emission layer, and a second electron transport portion, and a charge generation layer between the first emission part and the second emission part.

According to one or more embodiments of the present disclosure, a display device includes: a pixel including one or more sub-pixels, the sub-pixels each having an emission area to emit light and the pixel having a non-emission area around the emission areas of the sub-pixels; a pixel define layer overlapping a non-emission area and defining trenches in a boundary region between adjacent sub-pixels of the sub-pixels, the trenches penetrating the pixel define layer; an emission structure on portions of the trenches and the pixel define layer; and a cathode on the emission structure, wherein the thickness of a portion of the cathode overlapping the boundary region may be greater than the thickness of a portion of the cathode overlapping non-boundary regions adjacent to the boundary region.

According to one or more embodiments of the present disclosure, a display device includes: a pixel including one or more sub-pixels, the sub-pixels each having an emission area to emit light and the pixel having a non-emission area around the emission areas of the sub-pixels; a pixel define layer overlapping a non-emission area and defining trenches in a boundary region between adjacent sub-pixels of the subpixels, the trenches penetrating the pixel define layer; an emission structure on portions of the trenches and the pixel define layer; and a cathode on the emission structure, wherein the portion of the cathode overlapping the trenches has a gentle slope.

According to one or more embodiments of the present disclosure, a deposition mask includes: a frame, masking portions spaced and/or apart (e.g., spaced apart or separated) from each other in the frame, and support portions for fixing the masking portions in the frame, wherein the deposition mask defines openings between the frame, the masking portions, and the support parts.

In one or more embodiments, the structure of the masking portions may vary depending on the structure of sub-pixels to be deposited.

In one or more embodiments, the masking portions may correspond to non-boundary regions of the sub-pixels.

In one or more embodiments, the openings may correspond to a boundary region of the sub-pixels.

In one or more embodiments, the openings may allow a deposition material to pass through so that the deposition material is deposited on a cathode overlapping the boundary region.

According to one or more embodiments of the present disclosure, a method of manufacturing a display device includes: forming anodes on a planarization layer, forming a pixel define layer on portions of the anodes and the planarization layer, the pixel define layer defining sub-pixels at portions of the anodes where the pixel define layer is not located, forming trenches penetrating the pixel define layer in a boundary region between adjacent sub-pixels of the sub-pixels, forming an emission structure on portions of the trenches and the pixel define layer, forming a cathode on the emission structure, and irradiating a laser to a portion of the cathode overlapping the trenches.

In one or more embodiments, in irradiating the laser, the portion of the cathode overlapping the trenches may be melted to form a gentle slope.

In one or more embodiments, the thickness of the portion of the cathode overlapping the trenches may be less than that of a remaining portion not overlapping the trenches.

In one or more embodiments, the method may further include forming an encapsulation layer on the cathode.

### BRIEF DESCRIPTION OF THE DRAWINGS

The above and other aspects and features of the present disclosure will become more apparent by describing, in further detail, embodiments thereof with reference to the accompanying drawings, in which:

FIG. 1 is a block diagram of a display device according to one or more embodiments of the present disclosure.

FIG. 2 is a block circuit diagram of a sub-pixel according to one or more embodiments of the present disclosure.

FIG. 3 is a top view of a display panel according to one or more embodiments of the present disclosure.

FIG. 4 is an exploded perspective view of a part of a display panel according to one or more embodiments of the present disclosure.

FIG. 5 is a top view of a pixel according to one or more embodiments of the present disclosure.

FIG. 6 is a cross-sectional view taken along the line I-I′ in FIG. 5, according to one or more embodiments of the present disclosure.

FIG. 7 is a top view of a deposition mask according to one or more embodiments of the present disclosure.

FIG. 8 is a perspective view showing an example of applying a deposition mask according to one or more embodiments of the present disclosure.

FIG. 9 is a cross-sectional view of an emission structure according to one or more embodiments of the present disclosure.

FIG. 10 is a cross-sectional view of an emission structure according to one or more embodiments of the present disclosure.

FIG. 11 is a top view of a pixel according to one or more embodiments of the present disclosure.

FIG. 12 is a top view of a pixel according to one or more embodiments of the present disclosure.

FIG. 13 is a cross-sectional view taken along the line I-I′ in FIG. 5, according to one or more embodiments of the present disclosure.

FIGS. 14-19 are cross-sectional views showing a manufacturing process of a display device according to one or more embodiments of the present disclosure.

FIG. 20 is a block diagram of a display system according to one or more embodiments of the present disclosure.

FIG. 21 is a perspective view illustrating a head-mounted display device applying the display system of FIG. 20 according to one or more embodiments of the present disclosure.

FIG. 22 is a diagram illustrating the head-mounted display device of FIG. 21 worn by a user according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments according to the present disclosure will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected with/to,” or “coupled with/to” another element, it can be directly on, connected with/to, or coupled with/to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

The terminology used herein is for the purpose of describing particular embodiments only and is not intended to be limiting of the present disclosure. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof. As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “below,” “lower,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the singular forms “a,” “an” and “the” are intended to include the plural forms as well, unless the context clearly indicates otherwise. Further, as used herein, the terms “use,” “using,” and “used” may be considered synonymous with the terms “utilize,” “utilizing,” and “utilized,” respectively.

Various embodiments are described with reference to drawings that schematize ideal embodiments. Hence, it is to be expected that the shapes may vary depending on, for example, tolerances and/or manufacturing techniques. So, those embodiments disclosed herein should not be construed as being limited to the specific shapes illustrated, but should be construed to include, for example, changes in shapes that occur as a result of manufacturing. As such, the shapes depicted in the drawings may not reflect the actual shapes of regions of the apparatus, and the present embodiments are not limited thereby. In addition, in the drawings, the relative sizes of elements, layers, and regions may be exaggerated for clarity.

Unless otherwise noted, like reference numerals denote like elements throughout the attached drawings and the written description, and thus, duplicative descriptions thereof may not be provided.

Hereinafter, embodiments of the present disclosure will be described in detail with reference to the accompanying drawings.

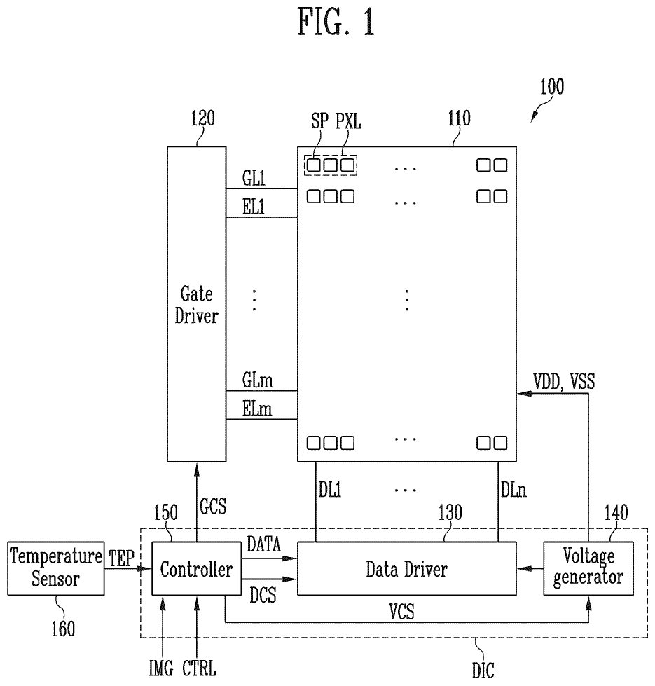

FIG. 1 is a block diagram of a display device according to one or more embodiments of the present disclosure.

With reference to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through the 1st to mth gate lines GL1 to GLm. The sub-pixels SP may be connected to the data driver 130 through the 1st to nth data lines DL1 to DLn.

Each of the sub-pixels SP may include at least one light-emitting element configured to emit light. Thus, each of the sub-pixels SP may be to emit light of a specific color, such as red, green, blue, cyan, magenta, or yellow. Two or more sub-pixels SP among the sub-pixels SP may form one pixel PXL. For example, as shown in FIG. 1, three sub-pixels SP may form one pixel PXL.

The gate driver 120 may be connected to sub-pixels SP arranged in the row direction through the 1st to mth gate lines GL1 to GLm. The gate driver 120 may output gate signals to the 1st to mth gate lines GL1 to GLm in response to a gate control signal GCS. The gate control signal GCS may include a start signal indicating the start of each frame, a horizontal synchronization signal for outputting gate signals in synchronization with the timing at which data signals are applied, and/or the like.

There may be further provided 1st to mth emission control lines EL1 to ELm connected to the sub-pixels SP in the row direction. In this case, the gate driver 120 may include an emission control driver configured to control the 1st to mth emission control lines EL1 to ELm, and the emission control driver may operate under the control of the controller 150.

The gate driver 120 may be arranged on a (e.g., one) side of the display panel 110. However, the present disclosure is not necessarily limited thereto. For example, the gate driver 120 may be divided into two or more drivers that are physically and/or logically separated, and such drivers may be arranged on one side of the display panel 110 and on the other side of the display panel 110 opposite to the one side. In this way, the gate driver 120 may be arranged around the display panel 110 in one or more suitable forms according to one or more embodiments.

The data driver 130 may be connected to the sub-pixels SP arranged in the column direction through the 1st to nth data lines DL1 to DLn. The data driver 130 may receive image data DATA and a data control signal DCS from the controller 150. The data driver 130 may operate in response to the data control signal DCS. The data control signal DCS may include a source start pulse, a source shift clock, a source output enable signal, and/or the like.

The data driver 130 may apply data signals having grayscale voltages corresponding to the image data DATA to the 1st to nth data lines DL1 to DLn by using voltages from the voltage generator 140. When a gate signal is applied to each of the 1st to mth gate lines GL1 to GLm, data signals corresponding to the image data DATA may be applied to the 1st to nth data lines DL1 to DLn. Hence, the corresponding sub-pixels SP may be to emit light corresponding to the data signals. Thereby, images may be displayed on the display panel 110.

The gate driver 120 and the data driver 130 may include complementary metal-oxide semiconductor (CMOS) circuit elements.

The voltage generator 140 may operate in response to the voltage control signal VCS from the controller 150. The voltage generator 140 may be configured to generate a plurality of voltages and provide the generated voltages to components of the display device 100. For example, the voltage generator 140 may be configured to generate a plurality of voltages by receiving an input voltage from outside the display device 100, adjusting the received voltage, and regulating the adjusted voltage.

The voltage generator 140 may generate a first power voltage VDD and a second power voltage VSS, and the generated first and second power voltages VDD and VSS may be supplied to the sub-pixels SP. The first power voltage VDD may have a relatively higher voltage level, and the second power voltage VSS may have a lower voltage level than the first power voltage VDD. However, the present disclosure is not necessarily limited thereto. For example, the first power voltage VDD or the second power voltage VSS may be supplied by an external equipment of the display device 100.

In addition, the voltage generator 140 may generate one or more suitable voltages. For example, the voltage generator 140 may generate an initialization voltage applied to the sub-pixels SP. For example, during sensing operation for sensing electrical characteristics of transistors and/or light-emitting elements of the sub-pixels SP, a preset reference voltage may be applied to the 1st to nth data lines DL1 to DLn, in which case the voltage generator 140 may generate such a reference voltage.

The controller 150 may control the overall operation of the display device 100. The controller 150 may receive input image data IMG and a control signal CTRL for controlling the display of the display panel 110 from the outside. The controller 150 may supply a gate control signal GCS, a data control signal DCS, and a voltage control signal VCS in response to the control signal CTRL.

The controller 150 may output image data DATA by converting the input image data IMG into a form suitable for the display device 100 or display panel 110. The controller 150 may output image data DATA by aligning the input image data IMG in a form suitable for sub-pixels SP of one row.

Two or more of the data driver 130, the voltage generator 140, and the controller 150 can be mounted on one integrated circuit. As shown in FIG. 1, the data driver 130, the voltage generator 140, and the controller 150 may be included in a driver integrated circuit DIC. In such a case, the data driver 130, the voltage generator 140, and the controller 150 may be functionally separate components within a single driver integrated circuit DIC. However, the present disclosure is not necessarily limited thereto. For example, at least one of the data driver 130, the voltage generator 140, and the controller 150 may be provided as a component separate from the driver integrated circuit DIC.

The display device 100 may include at least one temperature sensor 160. The temperature sensor 160 may be configured to sense the temperature of its surroundings and generate temperature data TEP indicating the sensed temperature. The temperature sensor 160 may be arranged adjacent to the display panel 110 and/or the driver integrated circuit DIC.

The controller 150 may control one or more suitable operations of the display device 100 in response to the temperature data TEP. The controller 150 may adjust the luminance of the image output from the display panel 110 in response to the temperature data TEP. For example, the controller 150 may adjust data signals and first and second power voltages VDD and VSS by controlling components such as the data driver 130 and/or the voltage generator 140.

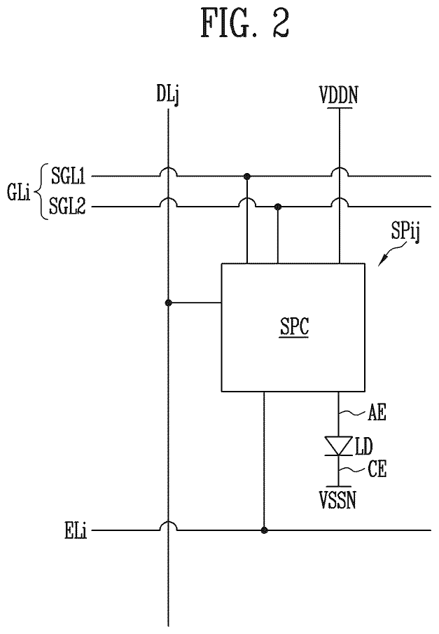

FIG. 2 is a block diagram of a sub-pixel according to one or more embodiments of the present disclosure.

In FIG. 2, a sub-pixel SPij arranged in the ith row (i is an integer greater than or equal to 1 and less than or equal to m) and the jth column (j is an integer greater than or equal to 1 and less than or equal to n) among the sub-pixels SP in FIG. 1 is illustrated.

With reference to FIG. 2, the sub-pixel SPij may include a sub-pixel circuit SPC and a light-emitting element LD.

The light-emitting element LD may be connected between a first power voltage node VDDN and a second power voltage node VSSN. Here, the first power voltage node VDDN is a node that delivers the first power voltage VDD in FIG. 1, and the second power voltage node VSSN is a node that delivers the second power voltage VSS in FIG. 1.

The anode AE of the light-emitting element LD may be connected to the first power voltage node VDDN through the sub-pixel circuit SPC, and the cathode CE of the light-emitting element LD may be connected to the second power voltage node VSSN. For example, the anode AE of the light-emitting element LD may be connected to the first power voltage node VDDN through one or more transistors included in the sub-pixel circuit SPC.

The sub-pixel circuit SPC may be connected to the ith gate line GLi among the 1st to mth gate lines GL1 to GLm in FIG. 1, the ith emission control line ELi among the 1st to mth emission control lines EL1 to ELm in FIG. 1, and the jth data line DLj among the 1st to nth data lines DL1 to DLn in FIG. 1. The sub-pixel circuit SPC may be configured to control the light-emitting element LD according to signals received through these signal lines.

The sub-pixel circuit SPC may operate in response to a gate signal received through the ith gate line GLi. The ith gate line GLi may include one or more sub-gate lines. As shown in FIG. 2, the ith gate line GLi may include first and second sub-gate lines SGL1 and SGL2. The sub-pixel circuit SPC may operate in response to gate signals received through the first and second sub-gate lines SGL1 and SGL2. In this way, if (e.g., when) the ith gate line GLi includes two or more sub-gate lines, the sub-pixel circuit SPC may operate in response to gate signals received through the corresponding sub-gate lines.

The sub-pixel circuit SPC may operate in response to an emission control signal received through the ith emission control line ELi. The ith emission control line ELi may include one or more sub-emission control lines. When the ith emission control line ELi includes two or more sub-emission control lines, the sub-pixel circuit SPC may operate in response to emission control signals received through the corresponding sub-emission control lines.

The sub-pixel circuit SPC may receive a data signal through the jth data line DLj. The sub-pixel circuit SPC may store a voltage corresponding to the data signal in response to at least one of the gate signals received through the first and second sub-gate lines SGL1 and SGL2. The sub-pixel circuit SPC may control the current flowing from the first power voltage node VDDN through the light-emitting element LD to the second power voltage node VSSN according to the stored voltage in response to the emission control signal received through the ith emission control line ELi. Thereby, the light-emitting element LD may be to emit light with a luminance corresponding to the data signal.

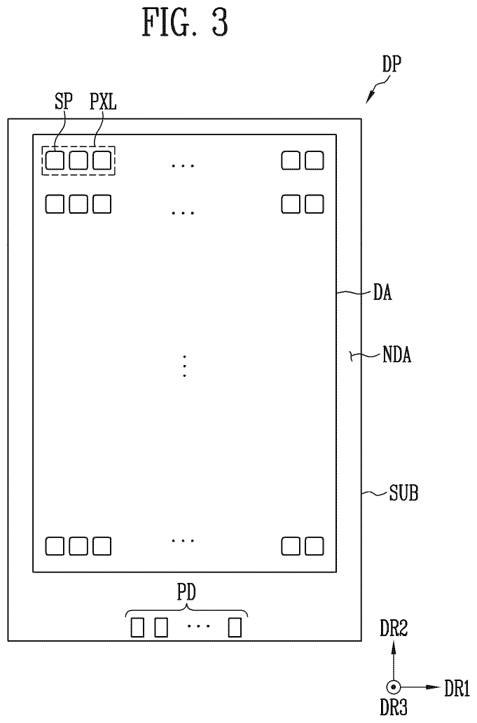

FIG. 3 is a top view of a display panel according to one or more embodiments of the present disclosure.

With reference to FIG. 3, the display panel DP (corresponding to the display panel 110 in FIG. 1) according to one or more embodiments may include a display area DA and a non-display area NDA. The display panel DP may display images through the display area DA. The non-display area NDA may be arranged around the display area DA.

The display panel DP may include a substrate SUB, sub-pixels SP, and pads PD.

When the display panel DP is used as a display screen of a head mounted display (HMD), virtual reality (VR) device, mixed reality (MR) device, augmented reality (AR) device, and/or the like, the display panel DP may be located very close to the user's eyes. In this case, sub-pixels SP with a relatively high integration level may be used. To increase the integration level of sub-pixels SP, a silicon substrate may be provided as the substrate SUB. The sub-pixels SP and/or the display panel DP may be formed on the substrate SUB being a silicon substrate. The display device 100 (see, e.g., FIG. 1) including a display panel DP formed on a substrate SUB being a silicon substrate may be referred to as an OLED on Silicon (OLEDOS) display device.

The sub-pixels SP may be arranged in the display area DA on the substrate SUB. The sub-pixels SP may be arranged in a matrix form along a first direction DR1 and a second direction DR2 intersecting the first direction DR1. However, the present disclosure is not necessarily limited thereto. For example, the sub-pixels SP may be arranged in a zigzag shape along the first direction DR1 and the second direction DR2. For example, the sub-pixels SP may be arranged in a PENTILE® shape (for example, an RGBG matrix or an RGBG structure). PENTILE® is a duly registered trademark of Samsung Display Co., Ltd. The first direction DR1 may be the row direction, and the second direction DR2 may be the column direction.

Two or more sub-pixels SP among a plurality of sub-pixels SP may constitute a (e.g., one) pixel PXL. In other words, a pixel PXL may include one or more sub-pixels SP, such as two or more sub-pixels SP.

Components for controlling the sub-pixels SP may be arranged in the non-display area NDA on the substrate SUB. For example, wiring lines connected to the sub-pixels SP, such as the 1st to mth gate lines GL1 to GLm and the 1st to nth data lines DL1 to DLn in FIG. 1, may be arranged in the non-display area NDA.

At least one of the gate driver 120, data driver 130, voltage generator 140, controller 150, and temperature sensor 160 in FIG. 1 may be integrated in the non-display area NDA of the display panel DP. The gate driver 120 in FIG. 1 may be mounted on the display panel DP and may be arranged in the non-display area NDA. However, the present disclosure is not necessarily limited thereto. For example, the gate driver 120 may be implemented as an integrated circuit separate from the display panel DP. The temperature sensor 160 may be arranged in the non-display area NDA to sense the temperature of the display panel DP.

The pads PD may be arranged in the non-display area NDA on the substrate SUB. The pads PD may be electrically connected to the sub-pixels SP through wiring lines. For example, the pads PD may be connected to the sub-pixels SP through the 1st to nth data lines DL1 to DLn.

The pads PD may interface the display panel DP to other components of the display device 100 (see, e.g., FIG. 1). Voltages and signals for the operation of components included in the display panel DP may be supplied from the driver integrated circuit DIC in FIG. 1 through the pads PD. For example, the 1st to nth data lines DL1 to DLn may be connected to the driver integrated circuit DIC through the pads PD. For example, the first and second power voltages VDD and VSS may be received from the driver integrated circuit DIC through the pads PD. For example, if (e.g., when) the gate driver 120 is mounted on the display panel DP, the gate control signal GCS may be transmitted from the driver integrated circuit DIC to the gate driver 120 through the pads PD.

A circuit board may be electrically connected to the pads PD through a conductive adhesive member such as an anisotropic conductive film. Here, the circuit board may be a flexible circuit board (FPCB) or flexible film having a flexible material. The driver integrated circuit DIC may be mounted on the circuit board to be electrically connected to the pads PD.

The display area DA may have one or more suitable shapes. The display area DA may have the shape of a closed loop including straight and/or curved sides. For example, the display area DA may have shapes such as a polygon, a circle, a semicircle, an ellipse, and/or the like.

The display panel DP may have a flat display surface. However, the present disclosure is not necessarily limited thereto. For example, the display panel DP may have at least in part a rounded display surface. The display panel DP may be bendable, foldable, or rollable. In these cases, the display panel DP and/or the substrate SUB may include materials having flexible properties.

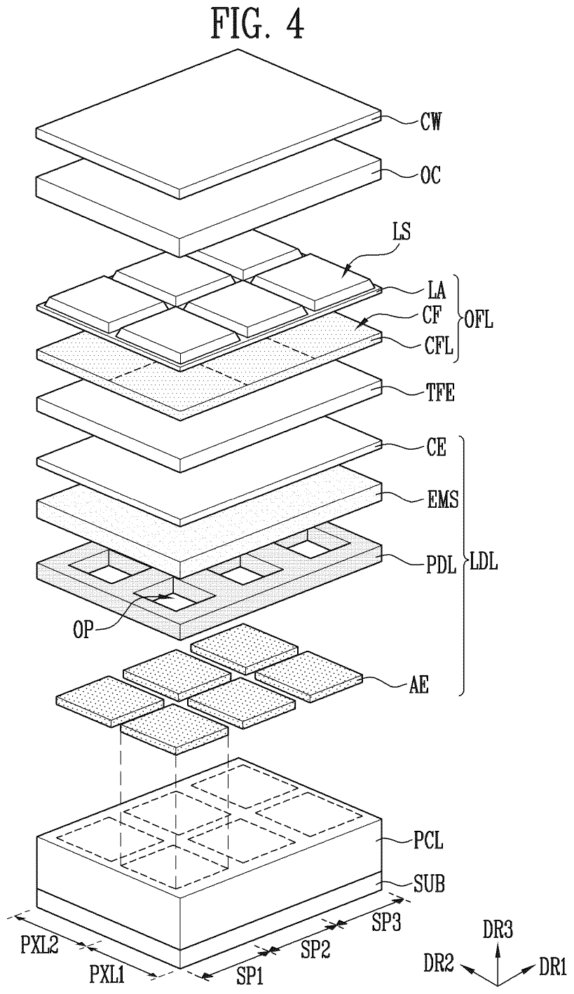

FIG. 4 is an exploded perspective view of a part of a display panel according to one or more embodiments of the present disclosure.

In FIG. 4, for clear and concise explanation, a part of the display panel DP corresponding to two pixels PXL1 and PXL2 among the pixels PXL in FIG. 3 is schematically illustrated. The part of the display panel DP corresponding to the remaining pixels may be constructed in a similar manner.

With reference to FIG. 4, each of the first and second pixels PXL1 and PXL2 may include first to third sub-pixels SP1, SP2 and SP3. However, the present disclosure is not necessarily limited thereto. For example, each of the first and second pixels PXL1 and PXL2 may include four sub-pixels SP or two sub-pixels SP.

The first to third sub-pixels SP1, SP2 and SP3 may have rectangular shapes and have the same sizes when viewed in a third direction DR3 intersecting the first and second directions DR1 and DR2. However, the present disclosure is not necessarily limited thereto. The first to third sub-pixels SP1, SP2 and SP3 may be modified to have one or more suitable shapes.

The display panel DP may include a substrate SUB, a pixel circuit layer PCL, a light-emitting element layer LDL, an encapsulation layer TFE, an optical function layer OFL, an overcoat layer OC, and a cover window CW.

The substrate SUB may include a silicon wafer substrate formed using a semiconductor process. The substrate SUB may include a semiconductor material suitable for forming circuit elements. For example, the semiconductor material may include silicon (Si), germanium (Ge), and/or silicon-germanium (SiGe). The substrate SUB may be provided from a bulk wafer, an epitaxial layer, a silicon-on-insulator (SOI) layer, or a semiconductor-on-insulator (SeOI) layer. However, the present disclosure is not necessarily limited thereto. For example, the substrate SUB may include a glass substrate or a polyimide (PI) substrate.

The pixel circuit layer PCL may be arranged on the substrate SUB. The substrate SUB and/or the pixel circuit layer PCL may include insulating layers and conductive patterns arranged between the insulating layers. The conductive patterns of the pixel circuit layer PCL may function as at least some of circuit elements, wiring lines, and the like. The conductive patterns may include copper, but the present disclosure is not necessarily limited thereto.

The circuit elements may include a sub-pixel circuit SPC (see, e.g., FIG. 2) of each of the first to third sub-pixels SP1, SP2 and SP3. The sub-pixel circuit SPC may include transistors and one or more capacitors. Each transistor may include a semiconductor portion including a source region, a drain region, and a channel region, and a gate electrode superimposed on the semiconductor portion. When the substrate SUB is provided as a silicon substrate, the semiconductor portion may be included in the substrate SUB, and the gate electrode may be included in the pixel circuit layer PCL as a conductive pattern of the pixel circuit layer PCL. When the substrate SUB is provided as a glass substrate or a PI substrate, the semiconductor portion and the gate electrode may be included in the pixel circuit layer PCL. Each capacitor may include electrodes spaced and/or apart (e.g., spaced apart or separated) from each other. For example, each capacitor may include electrodes spaced and/or apart (e.g., spaced apart or separated) from each other in a plane defined by the first and second directions DR1 and DR2. For example, each capacitor may include electrodes spaced and/or apart (e.g., spaced apart or separated) from each other in the third direction DR3 with an insulating layer interposed therebetween.

The wiring lines of the pixel circuit layer PCL may include signal lines, such as gate line, emission control line, and data line, connected to each of the first to third sub-pixels SP1, SP2 and SP3. The wiring lines may further include a wiring line connected to the first power voltage node VDDN in FIG. 2. Additionally, the wiring lines may further include a wiring line connected to the second power voltage node VSSN in FIG. 2.

The light-emitting element layer LDL may include anodes AE, a pixel define layer PDL, an emission structure EMS, and a cathode CE.

The anodes AE may be arranged on the pixel circuit layer PCL. The anodes AE may contact circuit elements of the pixel circuit layer PCL. The anodes AE may include an opaque conductive material capable of reflecting light, but the present disclosure is not necessarily limited thereto.

The pixel define layer PDL may be arranged on the anodes AE. The pixel define layer PDL may include an opening OP that exposes a portion of each of the anodes AE. The openings OP of the pixel define layer PDL may be understood as emission areas corresponding respectively to the first to third sub-pixels SP1 to SP3.

The pixel define layer PDL may include an inorganic material. In one or more embodiments, the pixel define layer PDL may include a plurality of stacked inorganic layers. For example, the pixel define layer PDL may include silicon oxide (SiOₓ, where 0<x≤2, e.g., SiO₂) and silicon nitride (SiNₓ, where 0<x≤2, e.g., Si₃N₄). However, the present disclosure is not necessarily limited thereto. For example, the pixel define layer PDL may include an organic material.

The emission structure EMS may be arranged on the anodes AE exposed by the openings OP of the pixel define layer PDL. The emission structure EMS may include an emission layer formed to emit light, an electron transport layer formed to transport electrons, and a hole transport layer formed to transport holes.

The emission structure EMS may be arranged overall on the pixel define layer PDL while filling the openings OP of the pixel define layer PDL. For example, the emission structure EMS may be extended across the first to third sub-pixels SP1 to SP3. In this case, at least some of the layers in the emission structure EMS may be disconnected or bent at the boundaries between the first to third sub-pixels SP1 to SP3. However, the present disclosure is not necessarily limited thereto. For example, parts of the emission structure EMS corresponding to the first to third sub-pixels SP1 to SP3 may be separated from each other, and these parts may be arranged respectively in the openings OP of the pixel define layer PDL.

The cathode CE may be arranged on the emission structure EMS. The cathode CE may be extended across the first to third sub-pixels SP1 to SP3. In this way, the cathode CE may be provided as a common electrode for the first to third sub-pixels SP1 to SP3.

The cathode CE may be a thin metal layer having a thickness sufficient to transmit light emitted from the emission structure EMS. The cathode CE may be made of a metal material or a transparent conductive material so as to have a relatively thin thickness. For example, the cathode CE may include at least one of various suitable transparent conductive materials such as indium tin oxide, indium zinc oxide, indium tin zinc oxide, aluminum zinc oxide, gallium zinc oxide, zinc tin oxide, and/or gallium tin oxide. However, the present disclosure is not necessarily limited thereto. For example, the cathode CE may include at least one of silver (Ag), magnesium (Mg), and (e.g., any suitable) mixtures thereof.

One among the anodes AE, a portion of the emission structure EMS overlapping therewith, and a portion of the cathode CE overlapping therewith may be understood as constituting one light-emitting element LD (see, e.g., FIG. 2). For example, each of the light-emitting elements LD of the first to third sub-pixels SP1 to SP3 may include one anode AE, a portion of the emission structure EMS overlapping therewith, and a portion of the cathode CE overlapping therewith. In each of the first to third sub-pixels SP1 to SP3, holes injected from the anode AE and electrons injected from the cathode CE are transported into the emission layer of the emission structure EMS to form excitons, and if (e.g., when) the excitons transition from an excited state to a ground state, light may be emitted. The luminance of the light may be determined by the amount of current flowing through the emission layer. Depending on the composition of the emission layer, the wavelength range of the emitted light may be determined.

The encapsulation layer TFE may be arranged on the cathode CE. The encapsulation layer TFE may cover the light-emitting element layer LDL and/or the pixel circuit layer PCL. The encapsulation layer TFE may be formed to prevent or reduce the likelihood of oxygen and/or moisture, and/or the like from penetrating into the light-emitting element layer LDL. The encapsulation layer TFE may include a structure in which one or more inorganic films and one or more organic films are alternately laminated. For example, the inorganic film may include silicon nitride, silicon oxide, or silicon oxynitride (SiOₓN_{y}. e.g., the range for x may be from 0 to 2, and the range for y may be from 0 to 4). For example, the organic film may include an organic insulating material such as acrylic resin, epoxy resin, phenol resin, polyamide resin, polyimide resin, unsaturated polyester resin, polyphenylene ether resin, polyphenylene sulfide resin, or benzocyclobutene (BCB). However, the present disclosure is not necessarily limited thereto.

To improve the encapsulation efficiency of the encapsulation layer TFE, the encapsulation layer TFE may further include a thin film containing aluminum oxide (AlOₓ). The thin film containing aluminum oxide may be arranged on the upper surface of the encapsulation layer TFE opposite to (e.g., facing) the optical function layer OFL and/or on the lower surface of the encapsulation layer TFE opposite to (e.g., facing) the light-emitting element layer LDL.

The thin film containing aluminum oxide may be formed by using an atomic layer deposition (ALD) method. However, the present disclosure is not necessarily limited thereto. The encapsulation layer TFE may further include a thin film made of at least one of various materials suitable for improving the encapsulation efficiency.

The optical function layer OFL may be arranged on the encapsulation layer TFE. The optical function layer OFL may include a color filter layer CFL and a lens array LA.

The color filter layer CFL may be arranged between the encapsulation layer TFE and the lens array LA. The color filter layer CFL may be formed to filter light emitted from the emission structure EMS to selectively output light of a wavelength range or color corresponding to each sub-pixel SP. The color filter layer CFL includes color filters CF corresponding respectively to the first to third sub-pixels SP1 to SP3, and each of the color filters CF may be to transmit light in a wavelength range corresponding to the associated sub-pixel SP. For example, the color filter CF corresponding to the first sub-pixel SP1 may be to transmit red color light, the color filter CF corresponding to the second sub-pixel SP2 may be to transmit green color light, and the color filter CF corresponding to the third sub-pixel SP3 may be to transmit blue color light. Depending on the light emitted from the emission structure EMS of each sub-pixel SP, at least some of the color filters CF may not be provided.

The lens array LA may be arranged on the color filter layer CFL. The lens array LA may include lenses LS corresponding respectively to the first to third sub-pixels SP1 to SP3. Each of the lenses LS may improve the light output efficiency by outputting the light emitted from the emission structure EMS to an intended path. The lens array LA may have a relatively high refractive index. For example, the lens array LA may have a higher refractive index than the overcoat layer OC. The lenses LS may include an organic material. For example, the lenses LS may include an acrylic material, but the present disclosure is not necessarily limited thereto.

At least some of the color filters CF of the color filter layer CFL and at least some of the lenses LS of the lens array LA may be shifted in a direction parallel to a plane defined by the first and second directions DR1 and DR2 with respect to the openings OP of the pixel define layer PDL. For example, in the central region of the display area DA, the center of the color filter CF and the center of the lens LS may be aligned with or overlapped with the center of the corresponding opening OP of the pixel define layer PDL when viewed in the third direction DR3. For example, in the central region of the display area DA, the opening OP of the pixel define layer PDL may completely overlap with the corresponding color filter CF of the color filter layer CFL and the corresponding lens LS of the lens array LA. In a region of the display area DA adjacent to the non-display area NDA, the center of the color filter CF and the center of the lens LS may be shifted in a plane direction from the center of the corresponding opening OP of the pixel define layer PDL when viewed in the third direction DR3. For example, in a region of the display area DA adjacent to the non-display area NDA, the opening OP of the pixel define layer PDL may overlap in part with (e.g., partially overlap) the corresponding color filter CF of the color filter layer CFL and the corresponding lens LS of the lens array LA. Thus, in the center of the display area DA, light emitted from the emission structure EMS may be efficiently output in the normal (e.g., perpendicular) direction of the display surface. At the periphery of the display area DA, light emitted from the emission structure EMS may be efficiently output in a direction inclined at a specific angle with respect to the normal (e.g., perpendicular) direction of the display surface.

The overcoat layer OC may be arranged on the lens array LA. The overcoat layer OC may cover the optical function layer OFL, the encapsulation layer TFE, the emission structure EMS, and/or the pixel circuit layer PCL. The overcoat layer OC may include one or more materials suitable for protecting layers thereunder from foreign substances such as dust or moisture. For example, the overcoat layer OC may include at least one of an inorganic insulating film and an organic insulating film. For example, the overcoat layer OC may include epoxy resin, but the present disclosure is not necessarily limited thereto. The overcoat layer OC may have a lower refractive index than the lens array LA.

The cover window CW may be arranged on the overcoat layer OC. The cover window CW may be formed to protect layers thereunder. The cover window CW may have a higher refractive index than the overcoat layer OC. The cover window CW may include glass, but the present disclosure is not necessarily limited thereto. For example, the cover window CW may be an encapsulation glass formed to protect components arranged thereunder. In one or more embodiments, the cover window CW may not be provided.

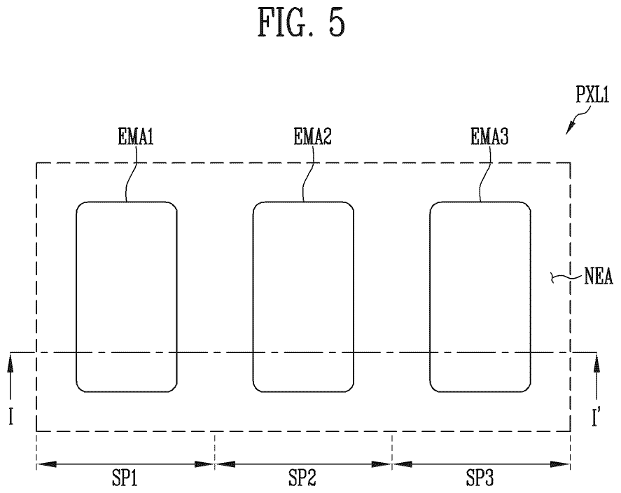

FIG. 5 is a top view of a pixel according to one or more embodiments of the present disclosure. In FIG. 5, the first pixel PXL1 among the first and second pixels PXL1 and PXL2 in FIG. 4 is schematically illustrated for clear and concise explanation. The remaining pixels PXL may be formed similarly to the first pixel PXL1.

With reference to FIG. 5, the first pixel PXL1 may include first to third sub-pixels SP1 to SP3 arranged in the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

The first emission area EMA1 may be a region where light is emitted from a portion of the emission structure EMS (see, e.g., FIG. 4) corresponding to the first sub-pixel SP1. The second emission area EMA2 may be a region where light is emitted from a portion of the emission structure EMS corresponding to the second sub-pixel SP2. The third emission area EMA3 may be a region where light is emitted from a portion of the emission structure EMS corresponding to the third sub-pixel SP3. As described with reference to FIG. 4, the emission areas (or the sub-pixels SP) may be understood as the openings OP of the pixel define layer PDL corresponding respectively to the first to third sub-pixels SP1 to SP3.

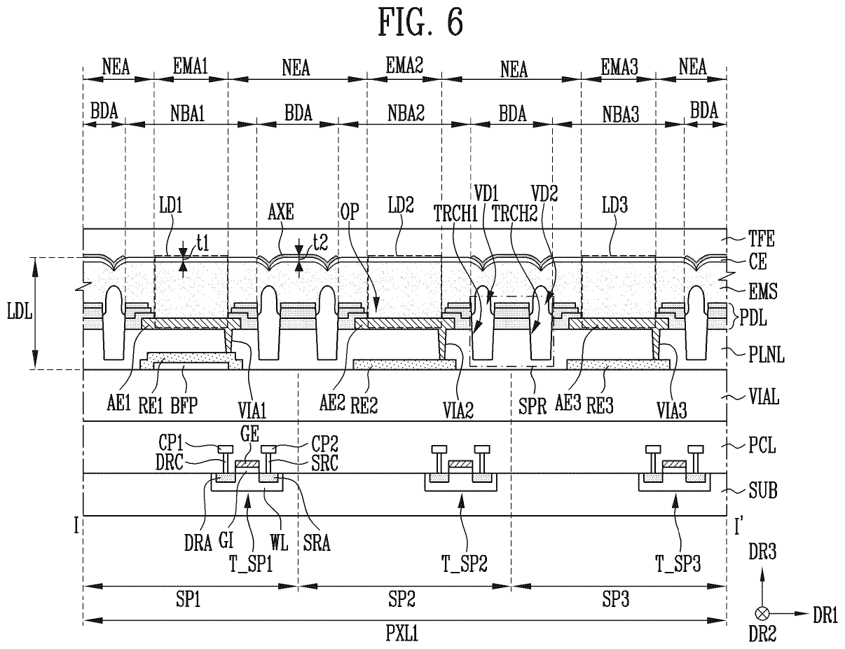

FIG. 6 is a cross-sectional view taken along the line I-I′ in FIG. 5 according to one or more embodiments of the present disclosure.

With reference to FIG. 6, the substrate SUB may include a silicon wafer substrate formed using a semiconductor process. For example, the substrate SUB may include silicon (Si), germanium (Ge), and/or silicon-germanium (SiGe).

The pixel circuit layer PCL may be arranged on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit SPC (see, e.g., FIG. 2) of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 6, for clarity and concise explanation, one of the transistors of each sub-pixel SP is illustrated, and the remaining circuit elements are not provided.

The transistor T_SP1 of the first sub-pixel SP1 may include a source region SRA, a drain region DRA, and a gate electrode GE.

The source region SRA and the drain region DRA may be arranged in the substrate SUB. A well WL formed through an ion implantation process is placed within the substrate SUB, and the source region SRA and the drain region DRA may be arranged to be spaced and/or apart (e.g., spaced apart or separated) from each other within the well WL. The region between the source region SRA and the drain region DRA within the well WL may be defined as a channel region.

The gate electrode GE may be arranged in the pixel circuit layer PCL so as to overlap the channel region between the source region SRA and the drain region DRA. The gate electrode GE may be separated from the well WL or channel region by an insulating material such as a gate insulating layer GI. The gate electrode GE may include a conductive material.

The plurality of layers included in the pixel circuit layer PCL may include insulating layers and conductive patterns arranged between the insulating layers, where the conductive patterns may include first and second conductive patterns CP1 and CP2. The first conductive pattern CP1 may be electrically connected to the drain region DRA via a drain connection DRC penetrating one or more insulating layers. The second conductive pattern CP2 may be electrically connected to the source region SRA via a source connection SRC penetrating one or more insulating layers.

As the gate electrode GE and the first and second conductive patterns CP1 and CP2 are connected to other circuit elements and/or wiring lines, the transistor T_SP1 of the first sub-pixel SP1 may be provided as one of the transistors of the first sub-pixel SP1.

Each of the transistor T_SP2 of the second sub-pixel SP2 and the transistor T_SP3 of the third sub-pixel SP3 may be formed similarly to the transistor T_SP1 of the first sub-pixel SP1.

In this way, the substrate SUB and the pixel circuit layer PCL may include circuit elements of each of the first to third sub-pixels SP1 to SP3.

A via layer VIAL may be arranged on the pixel circuit layer PCL. The via layer VIAL may have a flat surface on the whole while covering the pixel circuit layer PCL. The via layer VIAL may be formed to planarize steps on the pixel circuit layer PCL. The via layer VIAL may include at least one of silicon oxide (SiOₓ), silicon nitride (SiNₓ), and silicon carbon nitride (SiCN), but the present disclosure is not necessarily limited thereto.

The light-emitting element layer LDL may be arranged on the via layer VIAL. The light-emitting element layer LDL may include first to third reflective electrodes RE1 to RE3, a planarization layer PLNL, the first to third anodes AE1 to AE3, the pixel define layer PDL, the emission structure EMS, and the cathode CE.

On the via layer VIAL, the first to third reflective electrodes RE1 to RE3 may be arranged respectively in the first to third sub-pixels SP1 to SP3. Each of the first to third reflective electrodes RE1 to RE3 may contact a circuit element arranged in the pixel circuit layer PCL through a via penetrating the via layer VIAL.

The first to third reflective electrodes RE1 to RE3 may function as full mirrors that reflect light emitted from the emission structure EMS toward the display surface (or, cover window CW, see, e.g., FIG. 4). The first to third reflective electrodes RE1 to RE3 may include metal materials suitable for reflecting light. For example, the first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr) and titanium (Ti), and/or an alloy of two or more materials selected therefrom, but the present disclosure is not necessarily limited thereto.

A connection electrode may be arranged under each of the first to third reflective electrodes RE1 to RE3. The connection electrode may improve the electrical connection characteristics between the corresponding reflective electrode and circuit elements of the pixel circuit layer PCL. The connection electrode may have a multilayer structure. The multilayer structure may include titanium (Ti), titanium nitride (TiN), tantalum nitride (TaN), and/or the like, but the present disclosure is not necessarily limited thereto. For example, the corresponding reflective electrode may be positioned between the multilayers of the connection electrode.

A buffer pattern BFP may be arranged under at least one of the first to third reflective electrodes RE1 to RE3. The buffer pattern BFP may include an inorganic material such as silicon carbon nitride, but the present disclosure is not necessarily limited thereto. By arranging the buffer pattern BFP, the height of the corresponding reflective electrode in the third direction DR3 may be adjusted. For example, the buffer pattern BFP may be arranged between the first reflective electrode RE1 and the via layer VIAL to adjust the height of the first reflective electrode RE1.

The first to third reflective electrodes RE1 to RE3 may function as full mirrors, and the cathode CE may function as a half mirror. Light emitted from the emission layer of the emission structure EMS may be amplified at least partially by reciprocating between the corresponding reflective electrode and the cathode CE, and the amplified light may be output through the cathode CE. In this way, the distance between the reflective electrode and the cathode CE may be understood as the resonance distance for light emitted from the corresponding emission layer of the emission structure EMS.

The first sub-pixel SP1 may have a shorter resonance distance than other sub-pixels SP due to the buffer pattern BFP. The resonance distance adjusted in this way may effectively and efficiently amplify light in a specific wavelength range (e.g., red color). Hence, the first sub-pixel SP1 may effectively and efficiently output light in the corresponding wavelength range.

In FIG. 6, the buffer pattern BFP is illustrated as being provided to the first sub-pixel SP1 and not being provided to the second or third sub-pixel SP2 or SP3, but the present disclosure is not necessarily limited thereto. A buffer pattern BFP may also be provided to at least one of the second and third sub-pixels SP2 and SP3 so as to adjust the resonance distance of at least one of the second and third sub-pixels SP2 and SP3. For example, the first to third sub-pixels SP1 to SP3 may correspond respectively to red, green, and blue light; the distance between the first reflective electrode RE1 and the cathode CE may be shorter than the distance between the second reflective electrode RE2 and the cathode CE, and the distance between the second reflective electrode RE2 and the cathode CE may be shorter than the distance between the third reflective electrode RE3 and the cathode CE.

To planarize the steps between the first to third reflective electrodes RE1 to RE3, a planarization layer PLNL may be arranged on the via layer VIAL and the first to third reflective electrodes RE1 to RE3. The planarization layer PLNL may have a flat surface while covering the first to third reflective electrodes RE1 to RE3 and the via layer VIAL on the whole. In one or more embodiments, the planarization layer PLNL may not be provided.

On the planarization layer PLNL, the first to third anodes AE1 to AE3 may be arranged to overlap respectively with the first to third reflective electrodes RE1 to RE3. The first to third anodes AE1 to AE3 may have shapes similar to the first to third emission areas EMA1 to EMA3 in FIG. 5 when viewed in the third direction DR3. The first to third anodes AE1 to AE3 may be connected respectively to the first to third reflective electrodes RE1 to RE3. The first anode AE1 may be connected to the first reflective electrode RE1 through the first via VIA1 penetrating the planarization layer PLNL. The second anode AE2 may be connected to the second reflective electrode RE2 through the second via VIA2 penetrating the planarization layer PLNL. The third anode AE3 may be connected to the third reflective electrode RE3 through the third via VIA3 penetrating the planarization layer PLNL.

The first to third anodes AE1 to AE3 may include a conductive material. For example, the first to third anodes AE1 to AE3 may include at least one of transparent conductive materials such as indium tin oxide (ITO), indium zinc oxide (IZO), zinc oxide (ZnO), indium gallium zinc oxide (IGZO), and/or indium tin zinc oxide (ITZO). However, the present disclosure is not necessarily limited thereto. For example, the first to third anodes AE1 to AE3 may include titanium nitride.

Insulating layers may be further provided to adjust the height of one or more of the first to third anodes AE1 to AE3. The insulating layers may be arranged between one or more of the first to third anodes AE1 to AE3 and the corresponding reflective electrodes. In this case, the planarization layer PLNL and/or the buffer pattern BFP may not be provided. For example, the first to third sub-pixels SP1 to SP3 may correspond respectively to red, green, and blue; the distance between the first anode AE1 and the cathode CE may be shorter than the distance between the second anode AE2 and the cathode CE, and the distance between the second anode AE2 and the cathode CE may be shorter than the distance between the third anode AE3 and the cathode CE.

The pixel define layer PDL may be arranged on portions of the first to third anodes AE1 to AE3 and the planarization layer PLNL. The pixel define layer PDL may include openings OP exposing portions of the first to third anodes AE1 to AE3. The openings OP of the pixel define layer PDL may define the emission areas of the first to third sub-pixels SP1 to SP3. In this way, the pixel define layer PDL may define the first to third emission areas EMA1 to EMA3 while being arranged in the non-emission area NEA.

The pixel define layer PDL may include a plurality of inorganic insulating layers. Each of the plural inorganic insulating layers may include at least one of silicon oxide (SiOₓ) and silicon nitride (SiNₓ). For example, the pixel define layer PDL may include the first to third inorganic insulating layers laminated in sequence, and the first to third inorganic insulating layers may include silicon nitride, silicon oxide, and silicon nitride, respectively. The first to third inorganic insulating layers may have a step-shaped cross-section in the region adjacent to the opening OP. However, the present disclosure is not necessarily limited thereto. For example, the pixel define layer PDL may include organic insulating layers.

A separator SPR may be provided in a boundary region BDA between adjacent sub-pixels SP. The separator SPR may cause formation of a discontinuity in the boundary region BDA within the emission structure EMS. For example, the emission structure EMS may be cut or bent in the boundary region BDA due to the separator SPR.

The separator SPR may be provided in or on the pixel define layer PDL. The pixel define layer PDL may include one or more trenches TRCH1 and TRCH2 as a separator SPR in the boundary region BDA. As shown in FIG. 6, the one or more trenches TRCH1 and TRCH2 may penetrate the pixel define layer PDL and partially penetrate the planarization layer PLNL. However, the present disclosure is not necessarily limited thereto. For example, the one or more trenches TRCH1 and TRCH2 may penetrate the pixel define layer PDL and the planarization layer PLNL, and may partially penetrate the via layer VIAL. For example, the one or more trenches TRCH1 and TRCH2 may at least partially penetrate the planarization layer PLNL and/or the via layer VIAL, and a portion of the pixel define layer PDL may be arranged in the one or more trenches TRCH1 and TRCH2.

In FIG. 6, two trenches TRCH1 and TRCH2 are shown as being provided in the boundary region BDA. However, the present disclosure is not necessarily limited thereto. For example, the pixel define layer PDL may include one trench in the boundary region BDA. For example, the pixel define layer PDL may include three or more trenches in the boundary region BDA.

Due to the first and second trenches TRCH1 and TRCH2, discontinuous portions such as a first void VD1 and a second void VD2 may be formed in the boundary region BDA of the emission structure EMS. Some of the plural layers stacked in the emission structure EMS may be cut or bent due to the first and second voids VD1 and VD2. For example, at least one charge generation layer included in the emission structure EMS may be disconnected in the first and second voids VD1 and VD2. In this way, due to the first and second trenches TRCH1 and TRCH2, parts of the emission structure EMS included in the first to third sub-pixels SP1 to SP3 may be at least partially separated.

In FIG. 6, the first and second voids VD1 and VD2 are shown as being formed in the boundary region BDA of the emission structure EMS, but the present disclosure is not necessarily limited thereto. For example, a concave-shaped valley may be formed in the boundary region BDA of the emission structure EMS. Depending on the shapes of the first and second trenches TRCH1 and TRCH2, the discontinuous portions formed in the emission structure EMS may be modified in one or more suitable ways.

The emission structure EMS may be formed through processes such as vacuum deposition, inkjet printing, and/or the like. In one or more embodiments, materials substantially identical to the emission structure EMS may be positioned on the bottom surfaces adjacent to the via layer VIAL among (in) the first and second trenches TRCH1 and TRCH2.

The separator SPR may be provided in one or more suitable variations so that the emission structure EMS may have a discontinuous portion in the boundary region BDA.

The emission structure EMS may be arranged on the anodes AE exposed by the openings OP of the pixel define layer PDL. The emission structure EMS may be arranged overall across the first to third sub-pixels SP1 to SP3 while filling the openings OP of the pixel define layer PDL. As described above, the emission structure EMS may be at least partially cut or bent at the boundary region BDA due to the separator SPR. Hence, if (e.g., when) the display panel DP (see, e.g., FIG. 3) is operated, the current flowing from each of the first to third sub-pixels SP1 to SP3 to its neighboring sub-pixel SP through the layers included in the emission structure EMS may be reduced. Therefore, the first to third light-emitting elements LD1 to LD3 may operate with relatively high reliability.

The cathode CE may be arranged on the emission structure EMS. The cathode CE may be provided in common to the first to third sub-pixels SP1 to SP3. The cathode CE may function as a half mirror that partially transmits and partially reflects light emitted from the emission structure EMS.

The first anode AE1, a portion of the emission structure EMS overlapping the first anode AE1, and a portion of the cathode CE overlapping the first anode AE1 may constitute the first light-emitting element LD1. The second anode AE2, a portion of the emission structure EMS overlapping the second anode AE2, and a portion of the cathode CE overlapping the second anode AE2 may constitute the second light-emitting element LD2. The third anode AE3, a portion of the emission structure EMS overlapping the third anode AE3, and a portion of the cathode CE overlapping the third anode AE3 may constitute the third light-emitting element LD3.

The step coverage of the cathode CE may be degraded due to the first and second trenches TRCH1 and TRCH2 provided in the boundary region BDA, so that the cathode CE may be deposited unevenly (e.g., the coverage by the cathode CE may be degraded at the first and second trenches TRCH1 and TRCH2 due to the step). In other words, the cathode CE may have a partially uneven surface in the boundary region BDA. For example, the portions of the cathode CE that overlap the first and second trenches TRCH1 and TRCH2 (or, first and second voids VD1 and VD2) may have a relatively thin thickness and have a steeply sloped valley shape. In this case, the connectivity of the cathode CE may be degraded, and the cathode CE may be disconnected in severe cases.

An auxiliary electrode AXE may be partially arranged on the cathode CE. For example, the auxiliary electrode AXE may be arranged on a portion of the cathode CE that overlaps the boundary region BDA. The auxiliary electrode AXE may have a flat surface while covering a portion of the cathode CE overlapping the boundary region BDA. As the auxiliary electrode AXE is arranged on the portion of the cathode CE where the connectivity is weak, the connectivity can be supplemented. Hence, the operational reliability of the first to third light-emitting elements LD1 to LD3 may be increased. In addition, because the auxiliary electrode AXE is arranged on a portion of the cathode CE that overlaps the non-emission area NEA, it may not affect the luminance. The auxiliary electrode AXE may include a conductive material. For example, the auxiliary electrode AXE may include indium zinc oxide, aluminum, or silver, but the present disclosure is not necessarily limited thereto. In other words, the cathode CE may have an uneven surface in the boundary region BDA due to the first and second trenches TRCH1 and TRCH2, leading to potential connectivity issues and even disconnection in severe cases. To address this, an auxiliary electrode AXE may be arranged on the cathode CE in the boundary region BDA to supplement connectivity and improve the operational reliability of the light-emitting elements LD1 to LD3. The auxiliary electrode AXE, made of a conductive material like indium zinc oxide, aluminum, or silver, does not affect luminance as it overlaps the non-emission area NEA.

The auxiliary electrode AXE may be not arranged on portions of the cathode CE that overlap the first to third non-boundary regions NBA1 to NBA3 adjacent to the boundary regions BDA. The first non-boundary region NBA1 may be defined as a region including the first emission area EMA1 and a portion of the non-emission area NEA around the first emission area EMA1. The second non-boundary region NBA2 may be defined as a region including the second emission area EMA2 and a portion of the non-emission area NEA around the second emission area EMA2. The third non-boundary region NBA3 may be defined as a region including the third emission area EMA3 and a portion of the non-emission area NEA around the third emission area EMA3. In one or more embodiments, because the auxiliary electrode AXE is not arranged on the cathode CE overlapping the first to third emission areas EMA1 to EMA3, high optical characteristics can be maintained. If the auxiliary electrode AXE is arranged on the cathode CE overlapping the first to third emission areas EMA1 to EMA3, the thickness may increase and the transmittance of light emitted from the first to third emission areas EMA1 to EMA3 may decrease. For example, the luminance may decrease, so that the optical characteristics may deteriorate. In other words, the auxiliary electrode AXE is not placed on the cathode CE in the non-boundary regions NBA1 to NBA3 adjacent to the boundary regions BDA. These non-boundary regions NBA1 to NBA3 include the emission areas EMA1 to EMA3 and parts of the non-emission areas NEA around them. By not placing the auxiliary electrode AXE on the cathode CE in these emission areas EMA1 to EMA3, high optical characteristics are maintained. If the auxiliary electrode AXE were placed there, it would increase thickness and reduce light transmittance, leading to decreased luminance and deteriorated optical characteristics.

The thickness t2 of the conductive layer (i.e., cathode CE and auxiliary electrode AXE) overlapping the boundary region BDA may be greater than the thickness t1 of the conductive layer (i.e., cathode CE) overlapping the first to third non-boundary regions NBA1 to NBA3.

According to one or more embodiments, the auxiliary electrode AXE may be made of the same material as the cathode CE. In such embodiments, the auxiliary electrode AXE may be referred to as the cathode CE. Under these assumptions, the thickness t2 of the cathode CE overlapping the boundary region BDA may be greater than the thickness t1 of the cathode CE overlapping the first to third non-boundary regions NBA1 to NBA3. By forming the thickness of a portion of the cathode CE with weak connectivity (i.e., t2) thick and forming the thickness of a portion of the cathode CE that may cause a decrease in luminance (i.e., t1) thin, the connectivity of the cathode CE may be increased while maintaining high optical characteristics.

The encapsulation layer TFE may be arranged on the cathode CE and the auxiliary electrode AXE. The encapsulation layer TFE may prevent or reduce the likelihood of oxygen and/or moisture penetrating into the light-emitting element layer LDL.

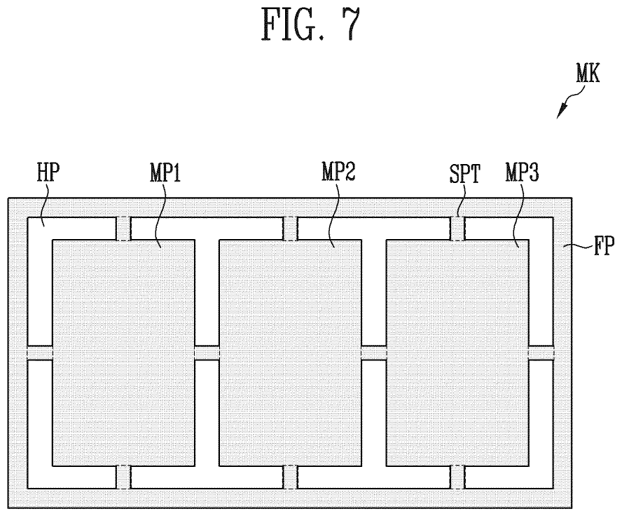

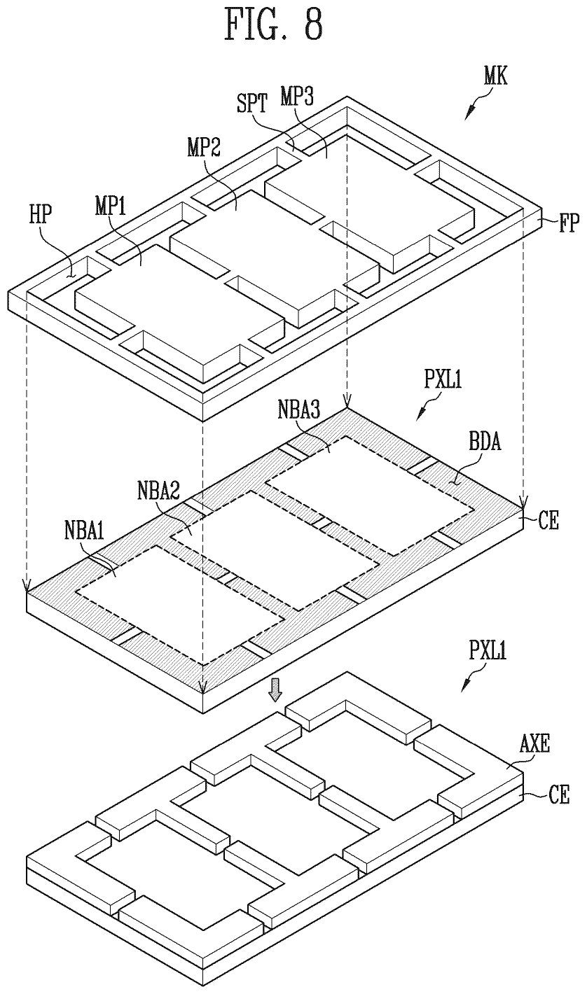

FIG. 7 is a top view of a deposition mask according to one or more embodiments of the present disclosure. FIG. 8 is a perspective view showing an example of applying the deposition mask according to one or more embodiments of the present disclosure. In FIG. 8, an auxiliary electrode AXE deposited on the first pixel PXL1 among the first and second pixels PXL1 and PXL2 in FIG. 4 is schematically illustrated for a clear and concise explanation. The auxiliary electrode AXE deposited at the remaining pixels PXL may be constructed in a similar manner.

With reference to FIGS. 7 and 8, the deposition mask MK may be a material used in the deposition process of the auxiliary electrode AXE described in FIG. 6. For example, the deposition mask MK may be a fine metal mask (FMM) made of a metal material or a fine silicon mask (FSM) made of a silicon (Si) material. The deposition mask MK may include a frame portion FP, first to third masking portions MP1 to MP3, support portions SPT, and openings HP.

The frame portion (or frame) FP may serve as a skeleton of the deposition mask MK and may be composed of the metal material or silicon material described above.

The first to third masking portions MP1 to MP3 may serve to protect regions where the auxiliary electrode AXE should not be deposited. The first masking portion MP1 may have a shape corresponding to the first non-boundary region NBA1 of the first pixel PXL1. The second masking portion MP2 may have a shape corresponding to the second non-boundary region NBA2 of the first pixel PXL1. The third masking portion MP3 may have a shape corresponding to the third non-boundary region NBA3 of the first pixel PXL1. For example, the first to third masking portions MP1 to MP3 may prevent or reduce the likelihood of the auxiliary electrode AXE being deposited on the cathode CE overlapping the first to third non-boundary regions NBA1 to NBA3. The structure of the first to third masking portions MP1 to MP3 may vary depending on the structure of the first to third sub-pixels SP1 to SP3 (see, e.g., FIG. 5) deposited.

The support portions SPT may serve to fix the first to third masking portions MP1 to MP3 to the frame portion FP. Additionally, the support portions SPT may serve to connect the first to third masking portions MP1 to MP3 to each other. For example, the support portions SPT may be arranged on the upper, lower, left, and right sides of each of the first to third masking portions MP1 to MP3. However, the present disclosure is not necessarily limited thereto, and the number or arrangement of the support portions SPT may be changed.

The support portions SPT may block the deposition of the auxiliary electrode AXE like the first to third masking portions MP1 to MP3. For example, the auxiliary electrode AXE may be not deposited on the cathode CE overlapping the support portions SPT. Because the auxiliary electrode AXE is an auxiliary layer to supplement the connectivity of the cathode CE, even if some auxiliary electrodes AXE are missing, the first pixel PXL1 may function to emit light normally.

The openings HP may be positioned between the frame portion FP, the first to third masking portions MP1 to MP3, and the support portions SPT. The openings HP may serve to allow deposition of the auxiliary electrode AXE. For example, the openings HP may cause the auxiliary electrodes AXE to be deposited on the cathode CE overlapping the boundary regions BDA of the first pixel PXL1. In FIG. 8, the hatched region of the first pixel PXL1 may indicate a region where the auxiliary electrode AXE is deposited. For example, the deposition material may pass through the openings HP and be deposited on the cathode CE overlapping the boundary regions BDA of the first pixel PXL1 to form auxiliary electrodes AXE.

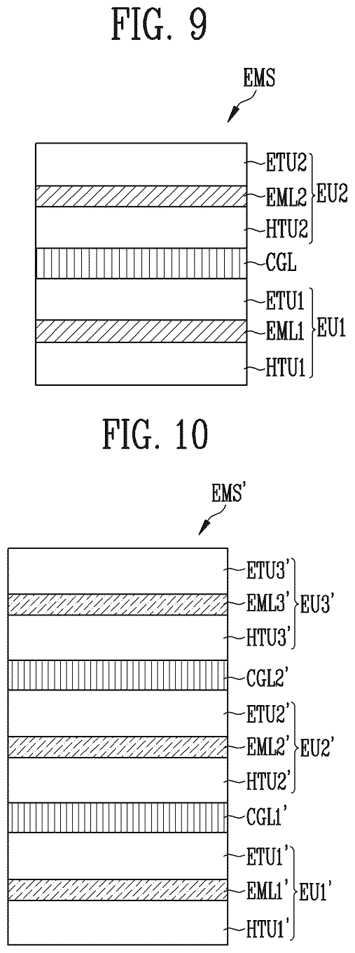

FIG. 9 is a cross-sectional view of the emission structure according to one or more embodiments of the present disclosure.

With reference to FIG. 9, the emission structure EMS may have a tandem structure in which the first and second emission parts EU1 and EU2 are stacked. In one or more embodiments, the emission structure EMS may be formed in substantially the same way in each of the first to third light-emitting elements LD1 to LD3 in FIG. 6.

Each of the first and second emission parts EU1 and EU2 may include at least one emission layer that emits light according to an applied current. The first emission part EU1 may include a first emission layer EML1, a first electron transport portion ETU1, and a first hole transport portion HTU1. The first emission layer EML1 may be arranged between the first electron transport portion ETU1 and the first hole transport portion HTU1. The second emission part EU2 may include a second emission layer EML2, a second electron transport portion ETU2, and a second hole transport portion HTU2. The second emission layer EML2 may be arranged between the second electron transport portion ETU2 and the second hole transport portion HTU2.

Each of the first and second hole transport portions HTU1 and HTU2 may include at least one of a hole injection layer and a hole transport layer, and may further include a hole buffer layer, an electron blocking layer, and/or the like if necessary or desired. The first and second hole transport portions HTU1 and HTU2 may have the same or different configurations.

Each of the first and second electron transport portions ETU1 and ETU2 may include at least one of an electron injection layer and an electron transport layer, and may further include an electron buffer layer, a hole blocking layer, and/or the like if necessary or desired. The first and second electron transport portions ETU1 and ETU2 may have the same or different configurations.

A connection layer, which may be provided in the form of a charge generation layer CGL, may be arranged between the first emission part EU1 and the second emission part EU2 to connect them to each other. The charge generation layer CGL may have a stacked structure of a p-dopant layer and an n-dopant layer. For example, the p-dopant layer may include a p-type (kind) dopant such as HAT-CN, TCNQ, NDP-9, and/or the like, and the n-dopant layer may include an alkali metal, an alkaline earth metal, a lanthanide metal, and/or a (e.g., any suitable) combination thereof. However, the present disclosure is not necessarily limited thereto.

The first emission layer EML1 and the second emission layer EML2 may be to emit light of different colors. The light emitted from the first emission layer EML1 and the second emission layer EML2 may be mixed and recognized as white light. For example, the first emission layer EML1 may be to emit blue light, and the second emission layer EML2 may be to emit yellow light. The second emission layer EML2 may include a structure in which a first sub-emission layer formed to emit red-colored light and a second sub-emission layer formed to emit green-colored light are stacked. Red-colored light and green-colored light may be mixed to produce yellow-colored light. In such a case, an intermediate layer formed to perform a function of transporting holes and/or a function of blocking the transport of electrons may be further arranged between the first and second sub-emission layers. However, the present disclosure is not necessarily limited thereto. For example, the first emission layer EML1 and the second emission layer EML2 may be to emit light of the same color.

FIG. 10 is a cross-sectional view of an emission structure according to one or more embodiments of the present disclosure.

With reference to FIG. 10, an emission structure EMS' may have a tandem structure in which first to third emission parts EU1′ to EU3′ are stacked. In one or more embodiments, the emission structure EMS' may be formed in substantially the same way in each of the first to third light-emitting elements LD1 to LD3 in FIG. 6.

Each of the first to third emission parts EU1′ to EU3′ may include an emission layer that emits light according to an applied current. The first emission part EU1′ may include a first emission layer EML1′, a first electron transport portion ETU1′, and a first hole transport portion HTU1′. The first emission layer EML1′ may be arranged between the first electron transport portion ETU1′ and the first hole transport portion HTU1′. The second emission part EU2′ may include a second emission layer EML2′, a second electron transport portion ETU2′, and a second hole transport portion HTU2′. The second emission layer EML2′ may be arranged between the second electron transport portion ETU2′ and the second hole transport portion HTU2′. The third emission part EU3′ may include a third emission layer EML3′, a third electron transport portion ETU3′, and a third hole transport portion HTU3′. The third emission layer EML3′ may be arranged between the third electron transport portion ETU3′ and the third hole transport portion HTU3′.

Each of the first to third hole transport portions HTU1′ to HTU3′ may include at least one of a hole injection layer and/or a hole transport layer, and may further include a hole buffer layer, an electron blocking layer, and the like if necessary or desired. The first to third hole transport portions HTU1′ to HTU3′ may have the same or different configurations.

Each of the first to third electron transport portions ETU1′ to ETU3′ may include at least one of an electron injection layer and an electron transport layer, and may further include an electron buffer layer, a hole blocking layer, and/or the like if necessary or desired. The first to third electron transport portions ETU1′ to ETU3′ may have the same or different configurations.

A first charge generation layer CGL1′ may be arranged between the first emission part EU1′ and the second emission part EU2′. A second charge generation layer CGL2′ may be arranged between the second emission part EU2′ and the third emission part EU3′.

The first to third emission layers EML1′ to EML3′ may be to emit light of different colors. The light emitted from each of the first to third emission layers EML1′ to EML3′ may be mixed and recognized as white light. For example, the first emission layer EML1′ may be to emit blue-colored light, the second emission layer EML2′ may be to emit green-colored light, and the third emission layer EML3′ may be to emit red-colored light. However, the present disclosure is not necessarily limited thereto. For example, two or more of the first to third emission layers EML1′ to EML3′ may be to emit light of the same color.

Unlike as shown in FIGS. 9 and 10, the emission structure EMS of FIG. 6 may include one emission part in each of the first to third light-emitting elements LD1 to LD3. In such embodiments, the emission parts included respectively in the first to third light-emitting elements LD1 to LD3 may be configured to emit light of different colors. For example, the emission part of the first light-emitting element LD1 may be to emit red-colored light, the emission part of the second light-emitting element LD2 may be to emit green-colored light, and the emission part of the third light-emitting element LD3 may be to emit blue-colored light. In such embodiments, unlike as shown in FIG. 6, the emission parts of the first to third sub-pixels SP1 to SP3 are separated from each other, and each of them may be arranged within an opening OP of the pixel define layer PDL.

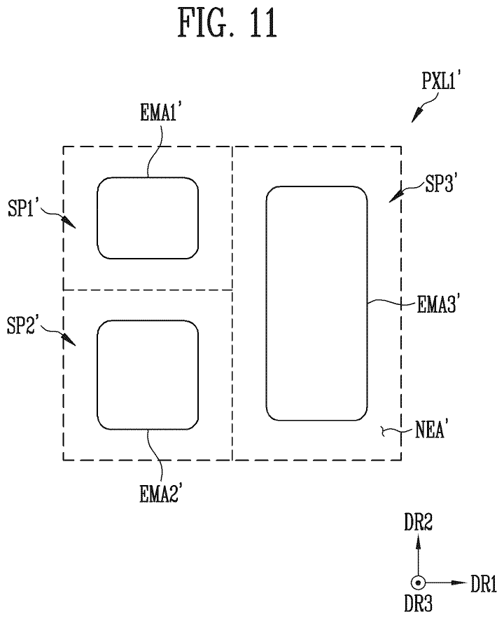

FIG. 11 is a top view of a first pixel according to one or more embodiments of the present disclosure.

With reference to FIG. 11, the first pixel PXL1′ may include first to third sub-pixels SP1′ to SP3′.

The first sub-pixel SP1′ may include a first emission area EMA1′ and a non-emission area NEA′ around the first emission area EMA1′. The second sub-pixel SP2′ may include a second emission area EMA2′ and a non-emission area NEA′ around the second emission area EMA2′. The third sub-pixel SP3′ may include a third emission area EMA3′ and a non-emission area NEA′ around the third emission area EMA3′.

The first sub-pixel SP1′ and the second sub-pixel SP2′ may be arranged in the second direction DR2. The third sub-pixel SP3′ may be arranged in the first direction DR1 with respect to the first and second sub-pixels SP1′ and SP2′.

The second sub-pixel SP2′ may have a larger area than the first sub-pixel SP1′, and the third sub-pixel SP3′ may have a larger area than the second sub-pixel SP2′. So, the second emission area EMA2′ may have a larger area than the first emission area EMA1′, and the third emission area EMA3′ may have a larger area than the second emission area EMA2′. However, the present disclosure is not necessarily limited thereto. For example, the first and second sub-pixels SP1′ and SP2′ may have substantially the same area, and the third sub-pixel SP3′ may have a larger area than each of the first and second sub-pixels SP1′ and SP2′. In this way, the areas of the first to third sub-pixels SP1′ to SP3′ may be varied in one or more suitable ways depending on the embodiment.

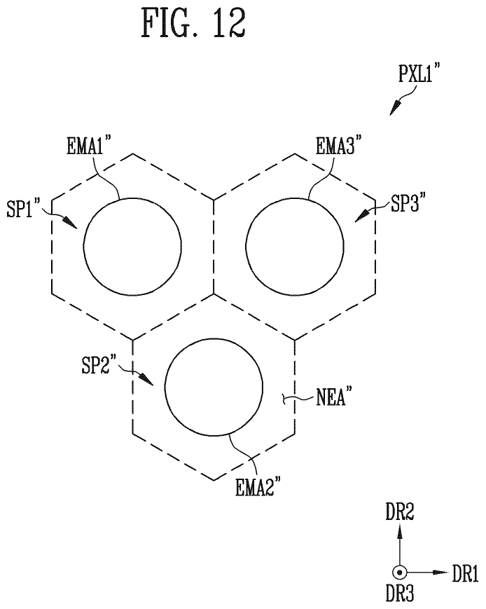

FIG. 12 is a top view of a first pixel according to one or more embodiments of the present disclosure.

With reference to FIG. 12, the first sub-pixel SP1″ may include a first emission area EMA1″ and a non-emission area NEA″ around the first emission area EMA1″. The second sub-pixel SP2″ may include a second emission area EMA2″ and a non-emission area NEA″ around the second emission area EMA2″. The third sub-pixel SP3″ may include a third emission area EMA3″ and a non-emission area NEA″ around the third emission area EMA3″.

The first to third sub-pixels SP1″ to SP3″ may have polygonal shapes when viewed in the third direction DR3. For example, the shapes of the first to third sub-pixels SP1″ to SP3″ may be hexagons as shown in FIG. 12.

The first to third emission areas EMA1″ to EMA3″ may have circular shapes when viewed in the third direction DR3. However, the present disclosure is not necessarily limited thereto. For example, each of the first to third emission areas EMA1″ to EMA3″ may have a polygonal shape.

The first and third sub-pixels SP1″ and SP3″ may be arranged in the first direction DR1. The second sub-pixel SP2″ may be arranged in a direction inclined at an acute angle with the second direction DR2 (or, in a diagonal direction) with respect to the first sub-pixel SP1″.

The arrangements of sub-pixels illustrated in FIGS. 5, 11 and 12 are for illustration purposes, and the present disclosure is not necessarily limited thereto. Each pixel may include two or more sub-pixels, the sub-pixels may be arranged in one or more suitable ways, the sub-pixels may have one or more suitable shapes, and their emission areas may also have one or more suitable shapes.

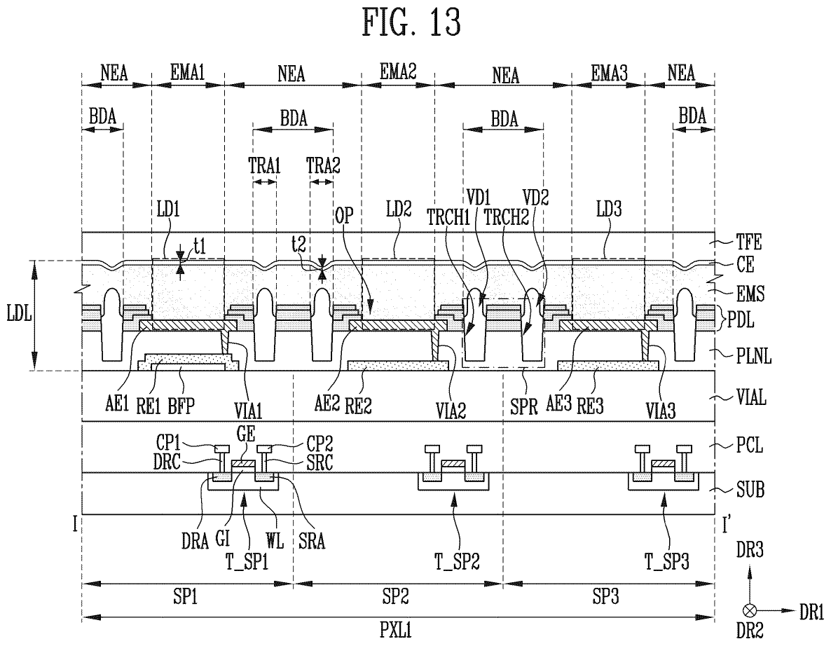

FIG. 13 is a cross-sectional view taken along the line I-I′ in FIG. 5 according to one or more embodiments of the present disclosure. With regard to FIG. 13, the description of contents overlapping those of FIG. 6 may be simplified or omitted.

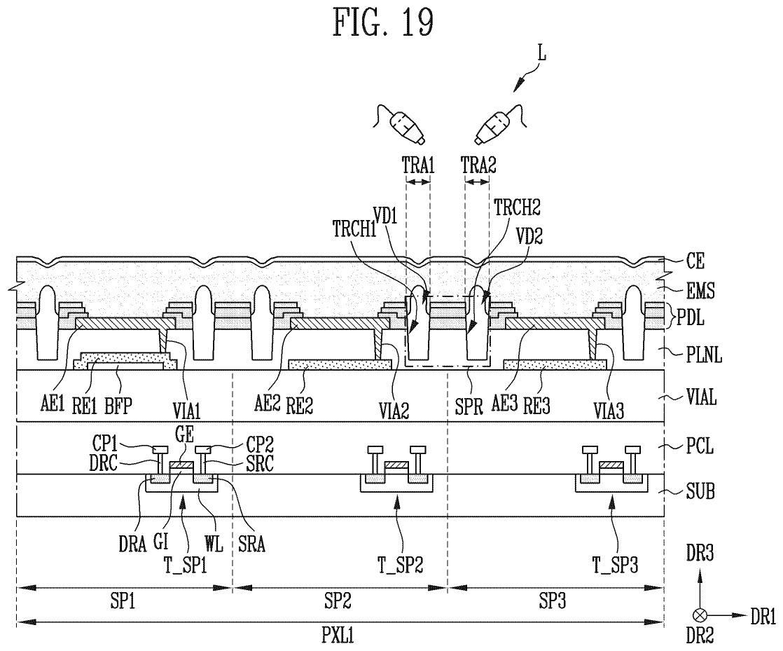

With reference to FIG. 13, the cathode CE overlapping the first and second trench regions TRA1 and TRA2 may have a gentle slope. The gentle slope may be characterized by a gradual and continuous transition from a higher to a lower point without abrupt changes in elevation to create a more uniform surface. Also, the first trench region TRA1 may indicate a region where the first trench TRCH1 is formed, and the second trench region TRA2 may indicate a region where the second trench TRCH2 is formed. While the connectivity is supplemented in FIG. 6 by forming an auxiliary electrode AXE on a portion of the cathode CE with weak connectivity, the connectivity may be supplemented in FIG. 13 by changing the shape of a portion of the cathode CE with weak connectivity. In this case, the thickness t2 of the cathode CE overlapping the first and second trench regions TRA1 and TRA2 may be smaller than the thickness t1 of the remaining portion of the cathode CE. This is because the cathode CE overlapping the first and second trench regions TRA1 and TRA2 is irradiated with a laser L (see, e.g., FIG. 19) and melted. In other words, the cathode CE overlapping the first and second trench regions TRA1 and TRA2 has a gentle slope. The first trench region TRA1 corresponds to the area where the first trench TRCH1 is formed, and the second trench region TRA2 corresponds to the area where the second trench TRCH2 is formed. Unlike FIG. 6, where an auxiliary electrode AXE is added to improve connectivity, FIG. 13 improves connectivity by reshaping the cathode CE. Consequently, the thickness t2 of the cathode CE in the trench regions TRA1 and TRA2 is less than the thickness t1 of the rest of the cathode CE, due to laser irradiation and melting in these regions.

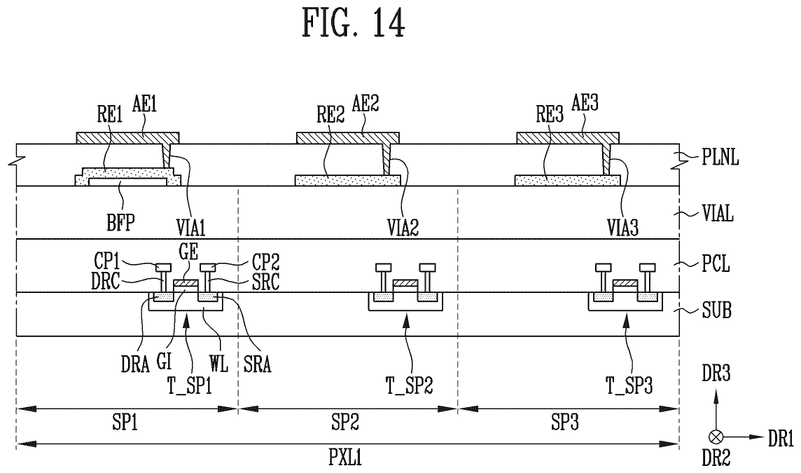

FIGS. 14 to 19 are cross-sectional views illustrating a manufacturing process of a display device according to one or more embodiments of the present disclosure. In FIGS. 14 to 19, the substrate SUB, pixel circuit layer PCL, via layer VIAL, planarization layer PLNL, and/or the like may be manufactured according to a suitable, generally utilized, and/or generally available manufacturing processes.

With reference to FIG. 14, the first to third anodes AE1 to AE3 may be patterned on the planarization layer PLNL. The first to third anodes AE1 to AE3 may be patterned respectively at positions corresponding to the first to third sub-pixels SP1 to SP3. The first to third anodes AE1 to AE3 may be patterned to penetrate the planarization layer PLNL and be connected respectively to the first to third reflective electrodes RE1 to RE3.

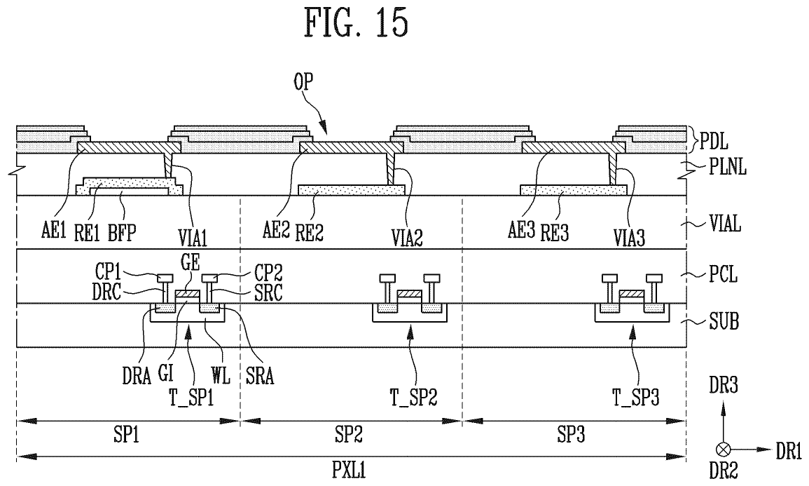

With reference to FIG. 15, the pixel define layer PDL may be patterned on the planarization layer PLNL and the first to third anodes AE1 to AE3. The pixel define layer PDL may be patterned in part on the first to third anodes AE1 to AE3 to have openings OP. Thereby, portions of the first to third anodes AE1 to AE3 corresponding to the openings OP may be exposed.

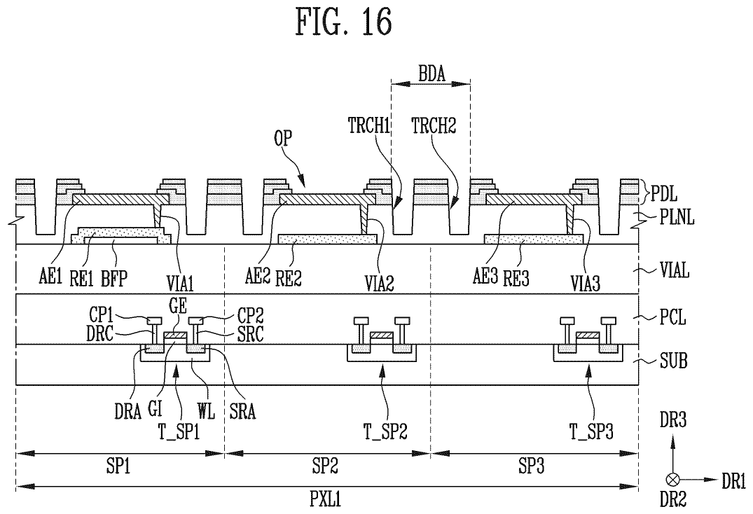

With reference to FIG. 16, the first and second trenches TRCH1 and TRCH2 may be patterned at positions overlapping the boundary region BDA. The first and second trenches TRCH1 and TRCH2 may be patterned so as to be spaced and/or apart (e.g., spaced apart or separated) from each other in the boundary region BDA and to penetrate the pixel define layer PDL and a portion of the planarization layer PLNL.

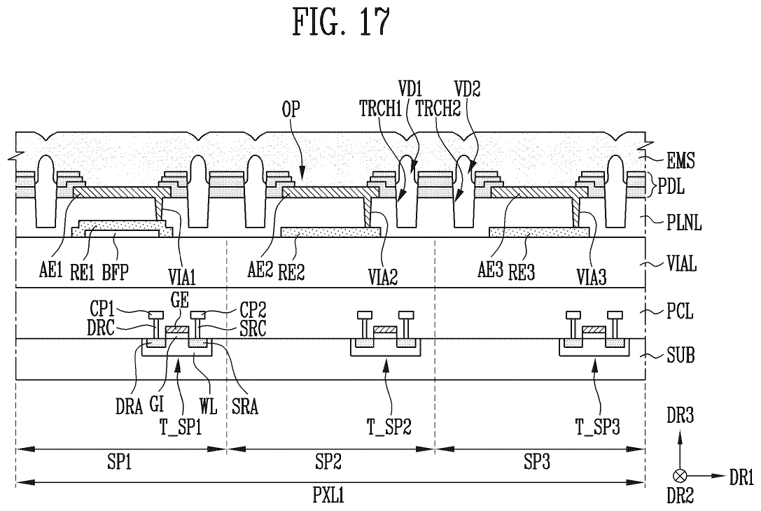

With reference to FIG. 17, the emission structure EMS may be patterned on the first to third anodes AE1 to AE3 and the pixel define layer PDL. In the process of patterning the emission structure EMS, first and second voids VD1 and VD2 may be formed due to the first and second trenches TRCH1 and TRCH2. The first and second voids VD1 and VD2 may cause the formation of a discontinuous portion in the emission structure EMS. Additionally, the portion of the emission structure EMS overlapping the first and second trenches TRCH1 and TRCH2 may be deposited unevenly to have a valley shape owing to a reduced step coverage (e.g., a reduction in coverage due to the step).

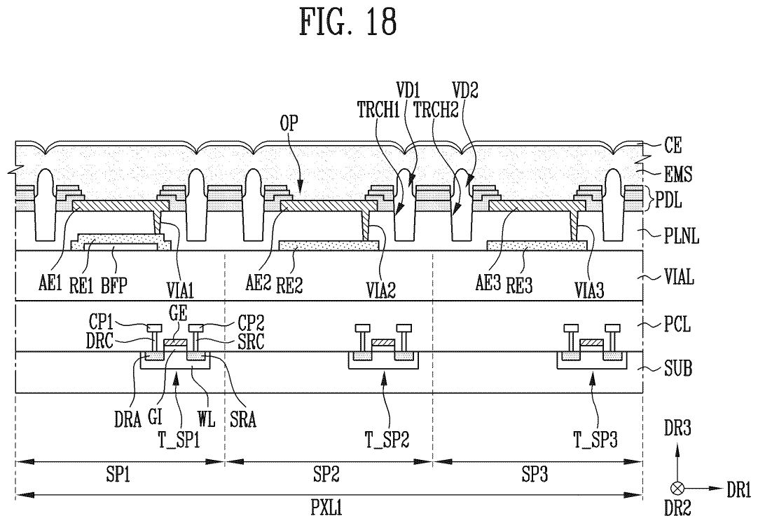

With reference to FIG. 18, the cathode CE can be patterned on the emission structure EMS. As described in FIG. 6, the portion of the cathode CE overlapping the first and second trenches TRCH1 and TRCH2 may be deposited unevenly to have the shape of a steeply inclined valley owing to a reduced step coverage (e.g., a reduction in coverage due to the step).

With reference to FIG. 19, the cathode CE may be partially irradiated with a laser L. For example, a laser L may be irradiated to a portion of the cathode CE with weak connectivity, that is, the portion of the cathode CE overlapping the first and second trench regions TRA1 and TRA2. In this case, the portion of the cathode CE overlapping the first and second trench regions TRA1 and TRA2 may be melted and its shape may be changed. For example, the portion of the cathode CE irradiated with the laser L may be melted to fill the steep valley, and the portion of the cathode CE overlapping the first and second trench regions TRA1 and TRA2 may then have a gentle slope. Consequently, the connectivity of the cathode CE may be increased and the risk of disconnection may be reduced. The laser L may be a laser used in a laser lift-off (LLO) process, but the present disclosure is not necessarily limited thereto. In other words, the cathode CE can be partially irradiated with a laser LS. For instance, the laser L may target a section of the cathode CE with weak connectivity, specifically the area overlapping the first and second trench regions TRA1 and TRA2. In this scenario, the targeted section of the cathode CE can be melted and reshaped. For example, the laser LS can melt the cathode CE to fill in steep valleys, resulting in a smoother, more gradual incline in the area overlapping the first and second trench regions TRA1 and TRA2. This gentle slope enhances the connectivity of the cathode CE and reduces the risk of disconnection. The gentle slope may be characterized by a gradual transition and continuous transition from a higher to a lower point without abrupt changes in elevation to create a more uniform surface. After securing the connectivity of the cathode CE, the encapsulation layer TFE (see, e.g., FIG. 13) may be formed on the cathode CE.

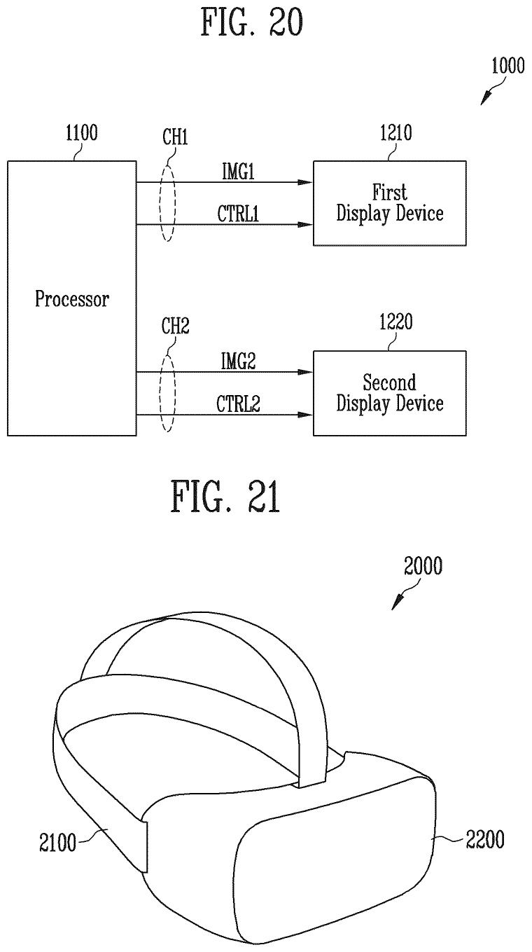

FIG. 20 is a block diagram of a display system according to one or more embodiments of the present disclosure.

With reference to FIG. 20, the display system 1000 may include a processor 1100 and one or more display devices 1210 and 1220.

The processor 1100 may perform one or more suitable tasks and calculations. The processor 1100 may include an application processor, a graphics processor, a microprocessor, a central processing unit (CPU), and/or the like. The processor 1100 may be connected to other components of the display system 1000 through a bus system and control them.

In FIG. 20, the display system 1000 is illustrated as including first and second display devices 1210 and 1220. The processor 1100 may be connected to the first display device 1210 through a first channel CH1 and to a second display device 1220 through a second channel CH2.

Through the first channel CH1, the processor 1100 may be to transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In such embodiments, the first image data IMG1 and the first control signal CTRL1 may be provided as the input image data IMG and the control signal CTRL in FIG. 1, respectively.

Through the second channel CH2, the processor 1100 may be to transmit second image data IMG2 and a second control signal CTRL2 to the second display device 1220. The second display device 1220 may display an image based on the second image data IMG2 and the second control signal CTRL2. The second display device 1220 may be configured similarly to the display device 100 described with reference to FIG. 1. In such embodiments, the second image data IMG2 and the second control signal CTRL2 may be provided as the input image data IMG and the control signal CTRL in FIG. 1, respectively.

The display system 1000 may include a computing system providing a video display function, such as a portable computer, a mobile phone, a smartphone, a tablet personal computer (PC), a smart watch, a watch phone, a portable multimedia player (PMP), a navigation equipment, and/or an ultra-mobile personal computer (UMPC). In addition, the display system 1000 may include at least one of a head mounted display (HMD), a virtual reality (VR) device, a mixed reality (MR) device, and an augmented reality (AR) device.

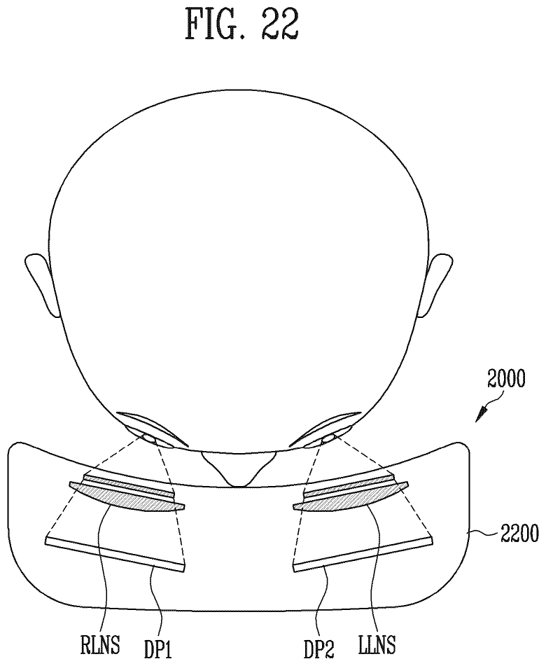

FIG. 21 is a perspective view showing an example of applying the display system of FIG. 20 according to one or more embodiments of the present disclosure.

With reference to FIG. 21, the display system 1000 of FIG. 20 may be applied to a head-mounted display device 2000. The head-mounted display device 2000 may be a wearable electronic device that can be worn on a user's head.

The head-mounted display device 2000 may include a head mount band 2100 and a display device storage case 2200. The head mount band 2100 may be connected to the display device storage case 2200. The head mount band 2100 may include a horizontal band and/or a vertical band for fixing the head-mounted display device 2000 to the user's head. The horizontal band may be formed to be around (e.g., surround) the side of the user's head, and the vertical band may be formed to be around (e.g., surround) the top of the user's head. However, the present disclosure is not necessarily limited thereto. For example, the head mount band 2100 may be implemented in the form of an eyeglass frame, a helmet, and/or the like.

The display device storage case 2200 may store the first and second display devices 1210 and 1220 of FIG. 20. The display device storage case 2200 may further store the processor 1100 of FIG. 20.

FIG. 22 is a drawing illustrating the head-mounted display device of FIG. 21 worn by the user according to one or more embodiments of the present disclosure.

With reference to FIG. 22, a first display panel DP1 of the first display device 1210 and a second display panel DP2 of the second display device 1220 may be arranged in the head-mounted display device 2000. The head-mounted display device 2000 may further include one or more lenses LLNS and RLNS.

Within the display device storage case 2200, the right eye lens RLNS may be arranged between the first display panel DP1 and the user's right eye. Within the display device storage case 2200, the left eye lens LLNS may be arranged between the second display panel DP2 and the user's left eye.

The image output from the first display panel DP1 may be shown to the user's right eye through the right eye lens RLNS. The right eye lens RLNS may refract light from the first display panel DP1 toward the user's right eye. The right eye lens RLNS may perform an optical function to adjust the viewing distance between the first display panel DP1 and the user's right eye.

The image output from the second display panel DP2 may be shown to the user's left eye through the left eye lens LLNS. The left eye lens LLNS may refract light from the second display panel DP2 toward the user's left eye. The left eye lens LLNS may perform an optical function to adjust the viewing distance between the second display panel DP2 and the user's left eye.

Each of the right-eye lens RLNS and the left-eye lens LLNS may include an optical lens having a cross-section in the shape of a pancake (e.g., a convex shape). Each of the right-eye lens RLNS and the left-eye lens LLNS may include a multi-channel lens that includes sub-regions with different optical characteristics. In such embodiments, each display panel may output images corresponding respectively to the sub-regions of the multi-channel lens, and the output images may pass through the corresponding sub-regions and be shown to the user.

Various embodiments of the present disclosure provide a display device that can maintain high optical characteristics while securing cathode connectivity, a method of manufacturing the display device, and a deposition mask.

However, aspects and features of the present disclosure are not limited to those described above, and one or more suitable other aspects and features would be understood by one of ordinary skill in the art within the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

The display device, an electronic apparatus, a device for manufacturing thereof, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a pixel comprising one or more sub-pixels, the sub-pixels each having an emission area to emit light and the pixel having a non-emission area around the emission areas of the sub-pixels;
a pixel define layer overlapping the non-emission area and defining trenches in a boundary region between adjacent sub-pixels of the sub-pixels, the trenches penetrating the pixel define layer;
an emission structure on portions of the trenches and the pixel define layer;
a cathode on the emission structure; and
an auxiliary electrode on a portion of the cathode.

2. The display device of claim 1, wherein the auxiliary electrode is on the portion of the cathode overlapping the boundary region.

3. The display device of claim 2, wherein:
the cathode overlaps non-boundary regions adjacent to the boundary region; and
the auxiliary electrode does not overlap the non-boundary regions.

4. The display device of claim 1, wherein the auxiliary electrode comprises a conductive material.

5. The display device of claim 4, wherein the auxiliary electrode comprises indium zinc oxide, aluminum, or silver.

6. The display device of claim 1, further comprising an encapsulation layer covering the cathode and the auxiliary electrode.

7. The display device of claim 1, wherein the emission structure comprises:
a first emission part comprising a first hole transport portion, a first emission layer, and a first electron transport portion;
a second emission part comprising a second hole transport portion, a second emission layer, and a second electron transport portion; and
a charge generation layer between the first emission part and the second emission part.

8. A display device comprising:
a pixel comprising one or more sub-pixels, the sub-pixels each having an emission area to emit light and the pixel having a non-emission area around the emission areas of the sub-pixels;
a pixel define layer overlapping the non-emission area and defining trenches in a boundary region between adjacent sub-pixels of the sub-pixels, the trenches penetrating the pixel define layer;
an emission structure on portions of the trenches and the pixel define layer; and
a cathode on the emission structure,
wherein a thickness of a portion of the cathode overlapping the boundary region is greater than a thickness of a portion of the cathode overlapping non-boundary regions adjacent to the boundary region.

9. A display device comprising:
a pixel comprising one or more sub-pixels, the sub-pixels each having an emission area to emit light and the pixel having a non-emission area around the emission areas of the sub-pixels;
a pixel define layer overlapping the non-emission area and defining trenches in a boundary region between adjacent sub-pixels of the sub-pixels, the trenches penetrating the pixel define layer;
an emission structure on portions of the trenches and the pixel define layer; and
a cathode on the emission structure,
wherein a portion of the cathode overlapping the trenches has a gentle slope.

10. A deposition mask comprising:
a frame;
masking portions spaced from each other in the frame; and
support portions for fixing the masking portions in the frame;
wherein the deposition mask defines openings between the frame, the masking portions, and the support parts.

11. The deposition mask of claim 10, wherein a structure of the masking portions varies depending on a structure of sub-pixels to be deposited.

12. The deposition mask of claim 11, wherein the masking portions correspond to non-boundary regions of the sub-pixels.

13. The deposition mask of claim 12, wherein the openings correspond to a boundary region of the sub-pixels.

14. The deposition mask of claim 13, wherein the openings allow a deposition material to pass through so that the deposition material is deposited on a cathode overlapping the boundary region.

15. A method for manufacturing a display device comprising:
forming anodes on a planarization layer;
forming a pixel define layer on portions of the anodes and the planarization layer, the pixel define layer defining sub-pixels at portions of the anodes where the pixel define layer is not located;
forming trenches penetrating the pixel define layer in a boundary region between adjacent sub-pixels of the sub-pixels;
forming an emission structure on portions of the trenches and the pixel define layer;
forming a cathode on the emission structure; and
irradiating a laser to a portion of the cathode overlapping the trenches.

16. The method of claim 15, wherein, in irradiating the laser, the portion of the cathode overlapping the trenches is melted to form a gentle slope.

17. The method of claim 16, wherein a thickness of the portion of the cathode overlapping the trenches is less than that of a remaining portion not overlapping the trenches.

18. The method of claim 15, further comprising forming an encapsulation layer on the cathode.
